(19) United States
(12) Patent Application Publication
(10) Pub. No.: US 2006/0081971 A1
(43) Pub. Date: Apr. 20, 2006

(54) SIGNAL TRANSFER METHODS FOR INTEGRATED CIRCUITS

(76) Inventor: Jeng Jye Shau, Palo Alto, CA (US)

Correspondence Address: Jeng Jye Shau, 991 Amarillo Ave., Palo Alto, CA, 94303, US

(21) Appl. No.: 11/163,564

(22) Filed: Oct. 23, 2005

Related U.S. Application Data
(63) Continuation-in-part of application No. 11/040,921, filed on Jan. 21, 2005.
Application No. 11/040,921 is a continuation-in-part of application No. 10/115,836, filed on Apr. 2, 2002.
Application No. 10/115,836 is a division of application No. 08/941,786, filed on Sep. 30, 1997, now Pat. No. 6,427,222.

(51) Int. Cl. G11C 8/00; H01L 23/48

(52) U.S. Cl. 257/690; 365/230.03

(57) ABSTRACT

The present invention discloses novel methods to transfer data between a plurality of integrated circuit blocks on a semiconductor wafer. Each individual circuit blocks contains internal circuits to control data transfer to nearby circuit blocks. Long distance signal transfer is achieved by a series of short distance data transfers. Such signal transfer methods provide many possible paths to transfer data between two points, allowing the possibility to bypass defective circuits. The present invention allows the possibility to integrate large amount of circuits into a single IC product while achieving excellent yield.

This is a continue-in-part application of U.S. application Ser. No. 11/040,921 filed Jan. 14, 2005. U.S. application Ser. No. 11/040,921 filed Jan. 14, 2005 is a continue-in-part application of U.S. application Ser. No. 10/115,836 filed Apr. 2, 2002. U.S. application Ser. No. 10/115,836 filed Apr. 2, 2002 is a division application of U.S. application Ser. No. 08/941,786 filed Sep. 30, 1997, now U.S. Pat. No. 6,427,222, issued Jul. 30, 2002.

This invention is in reference to three patent applications: a U.S. Pat. No. 6,427,222 (P222), and two co-pending patent applications with Ser. No. 10/115,836 (A836) and Ser. No. 11/040,921 (A921). All three references (P222, A836, A921) have the same titles as “Inter-Dice Wafer Level Signal Transfer Methods for Integrated Circuits”.

### FIELD OF THE INVENTION

The present invention relates to signal transfer methods for integrated circuits (IC), and particularly to signal transfer methods for large area IC using signal paths arranged in web structures.

### BACKGROUND OF THE INVENTION

Current art integrated circuit (IC) fabrication techniques involve formation of a plurality of individual IC devices on a single-crystal semiconductor substrate, termed a “wafer”. After fabrication and testing are completed, the wafer is scribed to separate the individual IC devices called “dice”. Each separated die is packaged for further integration with other IC and circuit elements. A packaged IC is called a “chip”. Sometimes, multiple dice of IC can be packaged into the same package. A packaged IC that has multiple sliced dice is called a “multiple chip module” (MCM). U.S. Pat. No 5,629,838 by Knight and U.S. Pat. No. 5,973,396 by Farnworth disclosed examples for MCM packaging technologies. Multiple packaged integrated circuits (single chip per package or MCM) are mounted on printed circuit boards (PCB) for electrical connections and mechanical supports. Multiple PCB modules are mounted into a box to form an electrical product such as a personal computer. Each assembly stage (IC->Chip->PCB->box) adds additional cost and increases occupied space. Each stage involves wide varieties of complex technologies that may cause yield losses. Each stage also adds additional loading to electrical connections that degrade performance and/or increase power consumption. It is therefore highly desirable to integrate as many circuits as possible into individual IC to reduce chip counts on modules. One classic example for chip count reduction is the “chip set” used in personal computers. In the past decades, IC industry has been trying to integrate as many circuits as possible into IC products as a method to reduce cost, volume, and power for electronic products. However, the size of prior art IC can not be increased without limitation. As discussed in A921, the chance to have manufacture defects in a die of prior art IC increases rapidly with increasing die size. Therefore, the cost of IC increases rapidly with die size due to area related yield loss. Another size limitation for current art IC is performance. For large IC manufactured by current art technologies, the resistance-capacitance (RC) delays of long signal lines are the dominating performance limiter. RC delays increase rapidly with increase in signal length. Performance problems caused by long signals are major factors limiting the size of IC. Size related yield problems and performance problems limited the number of circuits that can be integrated on prior art IC, and therefore limited the capability of prior art IC.

Prior art wafer level connections use small number of long lines (can be as long as the length of wafer) to connect a large number of dice. Such long lines can never support high performance operations, and they always cause yield problems. They are useful only for wafer level testing purpose. Examples for such prior art methods can be found in U.S. Pat. No. 5,053,900 by W. Parrish, U.S. Pat. No. 5,532,174 by Corrigan, U.S. Pat. No. 5,399,505 by Dasse et al, and U.S. Pat. No. 5,593,903 by Beckenbaugh et al.

The methods disclosed in references P222, A836, and A921 provided practical solutions to break the size barriers for IC. These methods provide capabilities to build large area integrated circuits with areas larger than 10 cm² or even as large as the whole wafer while achieving high yield and high performance. High bandwidth (greater than billions of bits per second) wafer level signal transfers between sources and destinations separated by inches or even across the whole wafer are also made practical.

The terminology “inter-dice connections” used in the present invention is in contrast with prior art “wafer level connections”. The inter-dice signal transfer methods disclosed in references P222, A836, and A921 execute wafer level long distance data transfer by a series of short distance inter-dice signal transfers controlled by inter-dice control logic circuits that typically include circuits such as multiplexers, buffers, latches, and control logic circuits. The inter-dice signal lines of the present invention are typically shorter than a few millimeters (mm) to reduce the effects of RC delay so that signal transfers can be executed at high performance (e.g. billions of bits per second per signal line) that is not possible for prior art wafer level connections that connect large number of dice at wafer level. These inter-dice signal lines are manufactured by IC technologies with excellent resolution so that we can easily have hundreds or thousands of lines between nearby dice. The available signal transfer bandwidth between nearby dice can easily reaches trillions of bits per second. Using multiple dimensional inter-dice signal transfer methods illustrated in the reference patents (P222, A836, A921), we can have multiple paths to transfer data between two points in IC circuits on the same substrate. In addition, we can have multiple data transfers executed simultaneously. The overall data transfer bandwidth in such design is therefore by far higher than prior art circuits. Such design also allows us to “go around” defected circuits so that the overall functionality of a large IC won't be destroyed by a few defects. This flexibility allow high yield even for IC as large as the whole wafer. As discussed in A921, these methods removed size limitations for integrated circuits. We can design an IC as large as the whole wafer and still have excellent yield while achieving extremely high performance with excellent data transfer bandwidth.

Many common terminologies used in IC industry need better definition after disclosure of P222, A836, and A921. For example, the term “die size” is commonly used to represent the area of a finished IC product. For prior art IC, “die size” equals the area of a finished IC because each IC comprises one and only one die. That is no longer true for IC products of the present invention because a finished IC product can have multiple dice. It is more accurate to say “the area of an IC”, instead of “the die size of an IC”. For historical reason, sometimes we still said “die size” instead of “area” in the reference patents (P222, A836, A921). For another example, the boundaries of a “die” were often defined by the “scribe lanes” reserved for die slicing for prior art IC. As discussed in A921, for an IC of the present invention, not all die boundaries are going to be sliced, and not all die boundaries are scribe lanes. Therefore, a “die” quoted in the present invention and in the reference patents (P222, A836, A921) are not necessarily defined by scribe lanes. For prior art IC products, a “die” can be defined as a unit that will be sliced out of a wafer because each prior art IC product only has one die. That is no longer a proper definition because an IC product of the present invention can have multiple dice; in some cases we can even use the whole wafer as one IC product. In A921, a die is defined as a block of integrated circuits that is repeated multiple times on the same wafer (at wafer level scale). A921 also defined new terminologies as “functional die” (FD) and “separable die” (SD). A “separable die” is completely surrounded by scribe lanes while a “functional die” is not necessarily completely surrounded by scribe lanes. For the present invention, not all separable dice are going to be sliced, but they have the option to be sliced. In prior art wafer there are no signal lines traveling between nearby dice; a wafer level signal needs to use conductor lines inches long. The terminology “inter-dice signal lines” of the present invention means short (a few mm) signal lines on the wafer traveling between and only between nearby dice on the same wafer. Signals can be transferred from one inter-dice signal line to another inter-dice signal line through control logic circuits or buffers/drivers between them. A wafer of the present invention can have a large number (thousands, millions, or billions) of such inter-dice signal lines while prior art wafer level signal lines are limited to small numbers. In prior art IC, wafer level signal transfers need to use wafer sized long lines or external probing. For an IC of the present invention, wafer level signal transfers are executed by a series of inter-dice signal transfers using short inter-dice signal lines.

In many ways, the data transfer structures of the present invention are similar in principle as the data transfer structures used by world-wide-web internet systems. In the present invention, we will call IC designed following the methods and structures of the present invention as “Web-IC”; the signal paths supporting signal transfers of the present invention will be called as “Web-IC signal paths” or “inter-dice signal lines”; and we will call design structures of the present invention as “Web-IC architecture”.

This invention provides further detailed discussions on the differences between prior art methods and the methods disclosed in the references (P222, A836, A921). In addition, this invention provides many application examples to demonstrate the operation principles of the present invention.

### SUMMARY OF THE INVENTION

The primary objective of the present invention is to break down the size barrier for IC devices to allow integration of extremely large circuits into an IC product. One objective of this invention is to improve data base search engineer using Web-IC of the present invention. Another objective of this invention is to improve routers using Web-IC of the present invention. Another objective of this invention is to improve the performances while reduce the costs of computers. Another objective of this invention is to increase the size limits and to improve the performances of field programmable logic array (FPGA) devices. Another objective of this invention is to provide extremely large capacity solid state storage devices at reasonable costs. These and other objectives of the present invention are achieved by data transfer methods of the present invention described in P222, A836, and A921.

While the novel features of the invention are set forth with particularly in the appended claims, the invention, both as to organization and content, will be better understood and appreciated, along with other objects and features thereof, from the following detailed description taken in conjunction with the drawings.

### BRIEF DESCRIPTION OF THE DRAWINGS

FIGS. 1(a-f) illustrate the differences between prior art IC and IC of the present invention;

FIGS. 2(a-k) show examples for applications of the present invention as data base search engine;

FIGS. 3(a, b) compare the differences between prior art solid state storage devices and storage devices of the present invention.

FIGS. 4(a-f) show examples for applications of the present invention as routers for communication systems;

FIGS. 5(a-d) show examples for applications of the present invention on computers; and

FIGS. 6(a-c) show examples for applications of the present invention as field programmable logic array (FPGA);

### DETAILED DESCRIPTION OF THE INVENTION

The present invention can be used for extremely powerful and complex applications. To facilitate clear understanding of complex applications, symbolic drawing and over-simplified examples are used in our discussions. Detailed circuit implementations and manufacture procedures that are well known to the arts are not repeated in our discussions. It should be understood that these particular examples are for demonstration only and are not intended as limitations on the present invention.

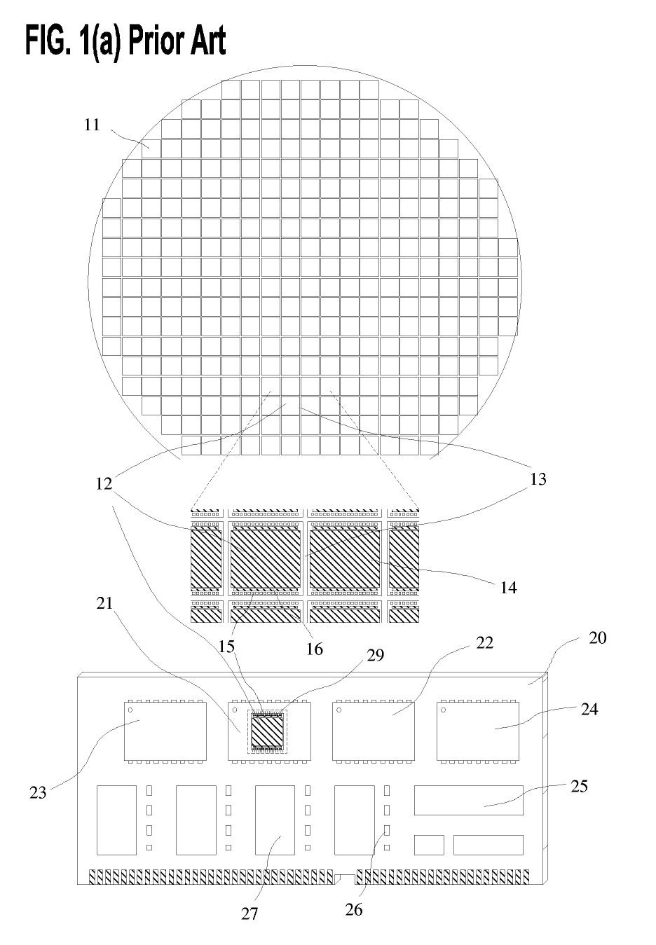

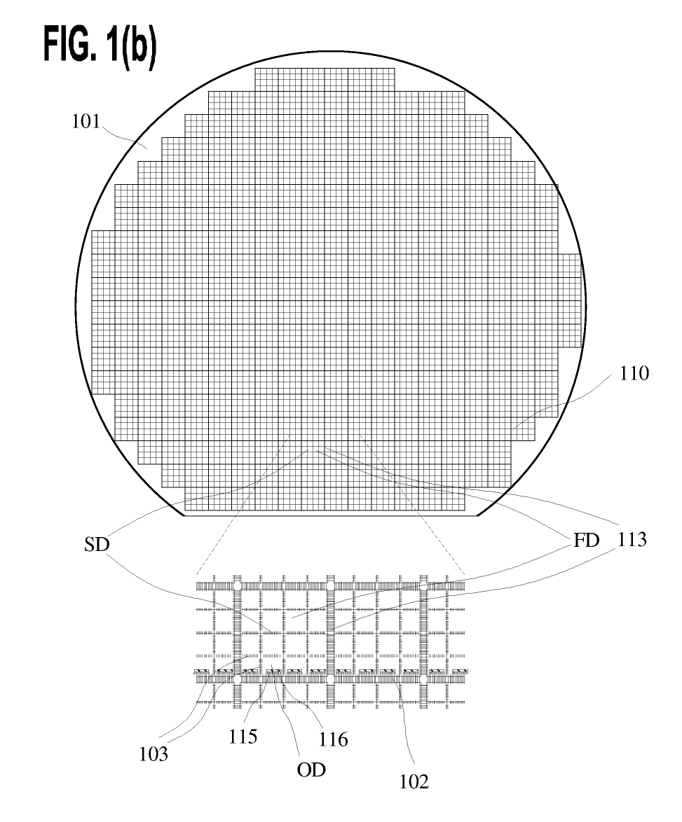

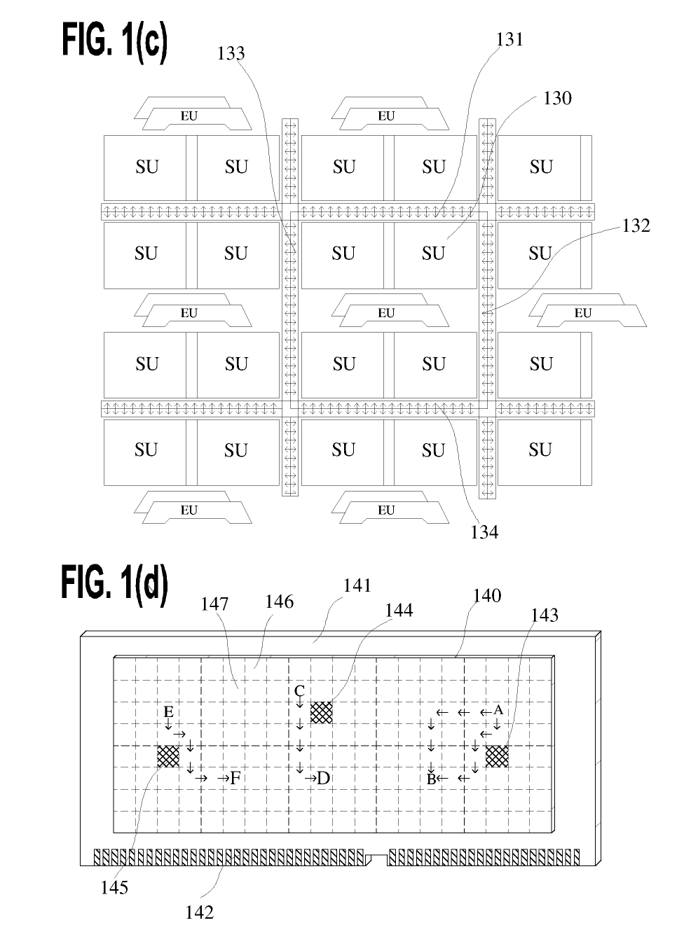

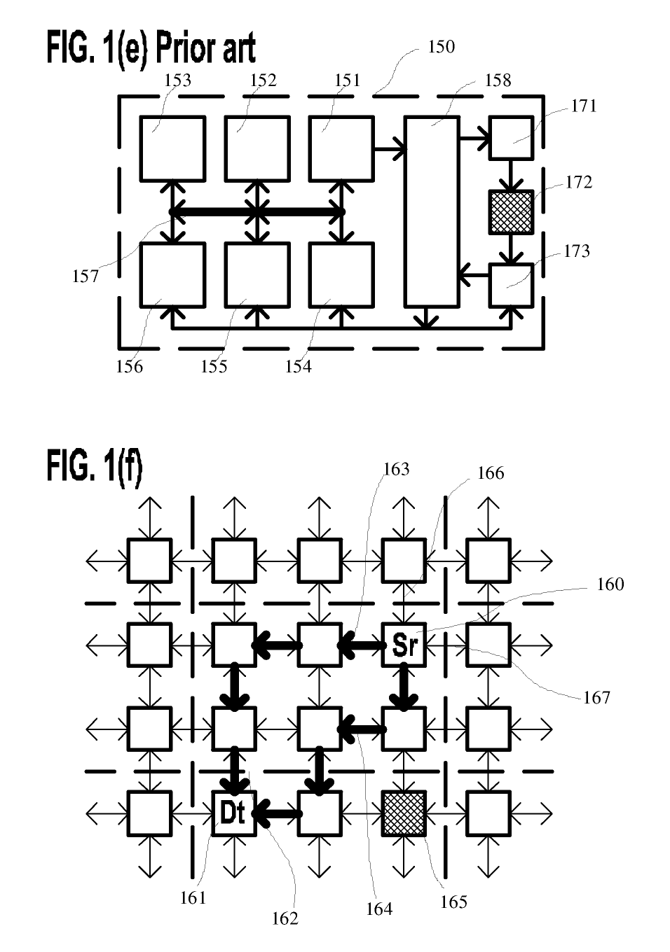

The differences between prior art IC and IC of the present invention are illustrated in FIGS. 1(a-f). FIG. 1(a) shows the structures of a wafer (11) for prior art IC, a magnified symbolic view for the structures of a prior art die (12) on the wafer, and the view when the prior die is placed on a PCB module (20). This wafer (11) comprises a plurality of wafer level repeating units called dice (12). Magnified symbolic structures for one example of such repeating units (12) are shown in FIG. 1(a) to reveal internal structures of individual die. For a prior art wafer, each die (12) is isolated from other dice and separated from nearby dice (14) by scribe lanes (13). For prior art IC, different dice are separated by scribe lanes, and there are no signal connections between nearby dice (12, 14) crossing the die boundaries. Sometimes, testing circuits (called “scribe lane test pattern”) maybe placed in the scribe lanes as testing monitors, but they are not used to transfer signals between nearby dice for finished products. Sometime, lone (inches) prior art wafer level connections are placed in the scribe lane to connect large number (more than 10) of dice using the same lines, but they are not used to transfer data only between nearby dice. After fabrication and testing are completed, the wafer is scribed to separate the dice (12, 14) into individual IC devices. Each prior art die (12) has a complete set of bounding pads (15) and input/output (I/O) circuits (16) for communicating with external circuits after the die (12) is cut from the wafer. Bounding wires (29) are used to connect the bounding pads to the pins of an IC package. Each separated die is packaged for further integration with other packaged IC (21, 22, 23, 24, 27) and circuit elements (25, 26) on a printed circuit board (20) as illustrated in FIG. 1(a).

FIG. 1(b) shows the structures of a wafer (101) for an IC of the present invention and magnified structures of the dice on the wafer. This wafer (101) comprises a plurality of repeating units called dice. For a prior art wafer, each die is isolated from other dice and separated from other dice by scribe lanes. A die of the present invention is not always surrounded by scribe lanes. For the example shown in FIG. 1(b), scribe lanes (110, 113) are represented by bold boundary lines on the wafer or channels (113, 102) in the magnified dice diagram. Using the terminology in A921, a unit that is surrounded by scribe lanes is called a “separable die” (SD) while a repeating unit at wafer level is called a “functional die” (FD). In this example, the scribe lanes (101, 102, 113) surround 16 functional dice (FD) to form one separable die (SD). The functional dice (FD) can be any type of integrated circuit, and we can have multiple types of function dice and/or separable dice on the wafer. A magnified symbolic picture in FIG. 1(b) reveals that the scribe lane (113, 102) and the functional die boundaries (103) can have large number of signal lines (represented by short line segments in FIG. 1(b)) going through die boundaries to provide signal transfer paths between nearby dice. Some of the functional dice (OD) can have bounding pads (115) and I/O circuits (116) for possible connections to external circuits. However, not all the functional dice (FD) need bounding pads and I/O circuits. Each I/O die (OD) also does not need to have a complete set of I/O signals because we can combine multiple OD to support one set of I/O signals.

FIG. 1(c) is a symbolic diagram showing an example for one of the functional die (FD) in FIG. 1(b). In this example, a functional die (130) comprises a dual-pipeline execution unit (EU) and 4 storage units (SU). Examples for execution units (EU) are arithmetic logic units (ALU), address generation units (AGU), graphic controllers, comparators, . . . etc. Examples for storage units (SU) are register files, random access memories (RAM), erasable/programmable read only memories (EPROM), content addressable memories (CAM), . . . etc. Such execution units (EUs) and storage units (SUs) are similar to those used by prior art IC circuits. Different from prior art IC, this functional die (130) has inter-dice signal lines (131) (represented symbolically by arrows in FIG. 1(c)) to communicate with the functional die above it, inter-dice signal lines (132) to communicate with the functional die to the right, inter-dice signal lines (133) to communicate with the functional die to the left, and inter-dice signal lines (134) to communicate with the functional die below it. Those nearby functional dice can have the same structures as this functional die (130), they also can have different structures and different functions. As discussed in our references (P222, A836, A921), such inter-dice communication circuits (131-134) form an extremely powerful communication network as illustrated in FIG. 1(d). From now on, we are going to use the terminology “Web-IC” as discussed previously. For this example, a piece of Web-IC (140) that comprises 10 separable dice (146) defined by bold dashed lines in FIG. 1(d); and each separable dice comprises 16 functional dice (147) defined by light dashed lines in FIG. 1(d). This Web-IC (140) is mounted on a printed circuit board (141). The printed circuit board (141) provides mechanical supports and electrical connections to the Web-IC (140). Supporting electrical components such as bypass capacitors, other ICs, or resisters (not shown) also can be mounted on the PCB. Metal pins (142) on the PCB (141) can provide interface connections to other system modules. For example, we can plug this module into standard PCI interface on personal computers. There are many methods to mount the Web-IC (140) on a printed circuit board (PCB). One of the preferred methods is to use a method similar to flip chip ball grid array (BGA) packaging method that has been developed for IC packaging. Such technologies places small solder balls directly on integrated circuits, and place the IC face down on the PCB. This type of bounding allows connections to the middle of the Web-IC (140). After heat treatments, the IC is bounded on the circuit board with excellent connections. One example of such packaging technology has been described in U.S. Pat. No. 5,970,396 by Farnworth. For prior art IC, the whole module fails if any one of the bounding fails; applying such packaging technologies on large area prior art IC is therefore not practical due to yield related cost problems. For the Web-IC (140) of the present invention, we can bypass failed components no matter the failure is caused by the IC itself or caused by PCB assembling processes. For the example shown in FIG. 1(d), we assume there are three dice (143, 144, 145, marked by cross lines) that are not available due to IC manufacture defects or assembling problems. We can simply avoid using those failed dice. When we want to transfer signals between different dice, we can go around the defective dice (143, 144, 145) using the web-IC signal transfers. FIG. 1(d) shows examples of Web-IC signal transfer (marked by arrow symbols) from die A to die B, from die C to die D, and from die E to die F. There are multiple ways to transfer signals between different dice; for example, FIG. 1(d) shows two paths to transfer data from die A to die B. Multiple signal transfers also can happen simultaneously due to the flexibility of such Web-IC signal transfer methods.

For simplicity in drawing, the Web-IC (140) in FIG. 1(d) comprises only 160 functional dice. In reality, a Web-IC of the present invention can have thousands of functional dice or more. For example, assume the size of the function dice (146) is 1 mm by 1 mm while the size of the Web-IC (140) is 40 mm by 100 mm, then the Web-IC has 4000 functional dice. The average yield of 1 mm×1 mm function dice should be better than 99%. Considering PCB assembly induced yield loss, we should still have better than 98% working functional dice. For prior art IC, one failure will fail the whole IC. For Web-IC, we can bypass the failed circuits using Web-IC signal transfers while utilizing the remaining functional circuits.

The present invention can be considered as a special method for signal transfers to large number of circuit blocks in integrated circuits. In prior art IC, signal transfers to multiple circuit blocks are typically provided using a group of signal lines called “bus”. One example of a prior art bus (157) is illustrated in a simplified block diagram in FIG. 1(e). In this example, 6 circuit blocks (151-156) share the same bus (157). Input and/or output signals between these circuit blocks (151-156) are placed on the bus (157) for communications between them. For prior art bus, there is one and only one way to send signals from a source to a destination (although a source may send the same signal to multiple destinations); if any one part of the bus is not functional (such as open circuit or short circuit on part of the bus lines), the whole chip is not functional. The loading on the bus increases with the number of circuit blocks using the bus. Therefore, the speed of the bus decreases with number of bus users. The speed of bus also decreases with the length of the bus due to RC delay. Prior art IC also can send signal in series of small steps but it is not the same as Web-IC signal transfers because those paths did not form web like structures allowing flexible transfer paths. In FIG. 1(e), the circuit block 151 can send signal to circuit block 173 through a serial path (151->158->171->172->173). With proper design, the overall signal transfer time using a series of small steps can be shorter than the time to send signal through a long line directly from block 151 to block 173. However, such prior art serial signal transfers still have one and only one way between the source circuit (151) and the destination circuit (173). If any one circuit along the path is not functional, the whole circuit fails. For example, if block 172 (marked by cross lines in FIG. 1(e)) fails, we can not send signal through previously mentioned signal path from the source circuit (151) and the destination circuit (173). Prior art signal paths and buses also never go through die boundaries. Prior art IC often have repeating circuit blocks within the die boundaries. For example, the circuit blocks (151-156) in FIG. 1(e) can be repeating blocks. But those repeating blocks do not extend out of die boundaries at wafer level with signal paths crossing die boundaries.

FIG. 1(f) is a simplified symbolic block diagram showing the basic structures for Web-IC of the present invention. A Web-IC comprises a plurality of dice or integrated circuit blocks (160, 161) on the same substrate, as represented by square blocks in FIG. 1(f). These repeating units are called “dice” in the references (P222, A836, A921). There maybe multiple types of dice, and the repeating distance expands out of conventional die boundaries. Scribe lanes (162) are represented by dashed lines in FIG. 1(f). Unlike prior art dice, dice boundaries of the present invention are not necessary scribe lanes (162). These dice are equipped with Web-IC signal lines, represented by arrows in FIG. 1(f), to communicate with nearby dice. For example, die 160 has Web-IC connection (166) to communicate with the dice above it, and Web-IC connection (167) to communicate with the die to its right. Within the dice (160, 161) there are Web-IC control circuits (not shown) that can transfer signals from one dice to multiple directions of nearby dice through Web-IC connections (166, 167). Typical components of Web-IC control circuits are multiplexers, drivers, buffers, latches, and logic circuits. These Web-IC connections go through die boundaries or scribe lanes (162) so that they can support wafer level long distance signal transfers. In the mean time, the length of each section of inter-dice signals is limited to be as short as local lines (shorter than a few mm) to achieve high performance. These Web-IC signal lines form a web network allowing high performance flexible signal transfers between all the circuits in Web-IC of the present invention. Long distance signal transfers are executed by a series of short distance Web-IC signal transfers. For example, the bold arrows in FIG. 1(f) illustrate a signal path (163) to send signal from a source circuit block (Sr) to a destination circuit block (Dt) through 4 steps of Web-IC signal transfers. Due to the Web-IC structure, there are multiple paths to send signal from a source to a destination. For example, there are two paths shown by bold arrows in FIG. 1(f) to transfer signals from Sr to Dt, and there are many other possible paths. This flexibility allows us to avoid failed or busy circuits (165) by choosing paths around the unavailable circuits (165). In this way, high yield or high utilization rate can be achieved for large area Web-IC, breaking size barriers of prior art IC.

In the references (P222, A836, A921), the signal transfer method illustrated in FIG. 1(f) are used to support wafer level signal transfers through signal transfers between nearby dice. Functional dice of the Web-IC still can use conventional signal transfer methods illustrated in FIG. 1(e) for local signal communications. It is realized that the Web-IC signal transfer methods are equally powerful for local signal transfers within function dice boundaries. The methods illustrated in FIG. 1(f) provide the advantages in performance and flexibility independent of the size of supported circuits. At larger scale, we also can arrange multiple packaged chips on PCB using such Web-IC architecture while providing similar advantages.

Web-IC of the present invention are different from prior art IC in many ways as discussed in the following sections.

A wafer of the present invention comprises a plurality of repeating units (at wafer level) called dice. We can have multiple types of such repeating units. The die boundaries are not necessary separated by scribe lanes. A prior art wafer typically comprises only one type of dice (with exceptions such as drop-in test patterns), while each die is separated from other dice by scribe lanes. In prior art wafer, there are no signal lines traveling across die boundaries to support signal transfer between and only between nearby dice. For IC of the present invention, there are inter-dice signal lines traveling through die boundaries to establish Web-IC signal transfer capabilities.

After wafer fabrication, there are multiple ways to cut Web-IC with different number of separable dice as IC products. We can even use the whole wafer as one IC product. Prior art IC always cut along the scribe lanes on dice boundaries with fixed die size. A prior art die must have a complete set of the bounding pads and I/O circuits needed for interface signals within every die. Web-IC of the present invention do not need to have all the pads and I/O circuits within one die because Web-IC can have multiple dice in an IC product.

Web-IC of the present invention executes long distance signal transfer through a series of short distance Web-IC signal transfers. Prior art IC also can break long distance signal transfer into a series of short distance signal transfers, but such prior art signal transfers do not go through die boundaries, limiting the overall signal transfer distance within conventional die size limits. Prior art IC can have long distance signal transfer using wafer level long lines that connect large number of dice on the same line, but the long lines limits performance and yield of prior art wafer level circuits.

The most significant difference is that signal transfer paths of the present invention form web-like communication paths. Such structures are similar in basic principles to the structures of internet communication systems. Between each pair of source and destination, there can be multiple paths available for signal transfers. This flexibility allows us to bypass failed/busy circuits to achieve high yield and to break down size barriers. Prior art IC has one and only one signal path between a source and a destination; a failed circuit along a signal path will fail the whole IC. Some prior art IC may have “redundancy circuits” to replace failed circuits. The prior art redundancy circuit is useful to replace failed circuit blocks it is designed to replace, and the redundancy circuits are idle when there is no need to use the redundancy circuits. The Web-IC is by far more flexible then prior art redundancy, and we can utilize all functional circuits. Unlike prior art redundancy circuits, the present invention is not a method setting aside extra circuits waiting to replace failed circuits (although IC of the present invention also can have conventional redundancy circuits to further improve yield). The Web-IC connections of the present invention provide the flexibility in bypassing defective circuits. The defective circuits maybe generated during IC manufacturing, during packaging, or even caused by reliability problem in the fields. The Web-IC architecture provides the flexibility to live with those problems.

While specific embodiments of the invention have been illustrated and described herein, other modifications and changes will occur to those skilled in the art. It should be understood that these particular examples are for demonstration only and are not intended as limitations on the present invention. Although the above discussions focused on inter-dice connections between nearby dice, the Web-IC architecture can have many variations. For example, local circuit blocks also can use web-like signal transfer methods to improve yield and performance. At higher level, it is also a good practice to have a higher level web that transfer signals through a few dice instead of just between dice right next to each other. Not all signals should be implemented in Web-IC structures. Power lines or clock signals may still use long thick lines like conventional wafer level connections. The actual Web-IC certainly should combine the advantages of Web-IC transfer methods with conventional methods to reach optimum advantages. The functional dice in the Web-IC of the present invention can be any size and shapes. We can have multiple types of functional dice in the same Web-IC with different sizes and shapes. However, the sizes of functional dice tend to be smaller than a few mm on each side in order to achieve better performance. The basic methods and structures of Web-IC were first disclosed in the original patent P222 filed in 1997. Since 1997, the IC manufacture technologies have advanced from 350 nm (10⁻⁹ meter) technologies into 65 nm technologies and currently moving into 45 nm technologies. Logic gate delay time were measured in ns (10⁻⁹ second) in 1997; now it is measured in ps (10⁻¹² second). The Web-IC technology also needs to make adjustments according to the advances in manufacture technologies. For example, in 997, we needed to find ways to overcome the barriers caused by seal rings to provide inter-dice connections through scribe lanes. That was why P222 discussed many ways to overcome the barrier. After copper started to replaces aluminum as the internal metal connection material for IC, it is a common practice to deposit metal connections on top of wafer to protect copper from chemical reactions with air. We can easily use the top metal layer(s) for inter-dice connections without any changes to existing manufacture procedures in IC manufacture technologies. In addition, wafer level bumping technologies are also becoming a common packaging technology. Such technologies provide convenient ways to implement inter-dice connections and/or power lines without changes to existing manufacture procedures. In many ways, implementing inter-dice connections using advanced IC technologies is actually easier than implementing it into older technologies. The value of the present invention increases with the progress in IC technology, and this trend will continue in the foreseeable future.

The present invention is a method for signal transfers between a plurality of integrated circuit blocks on the same semiconductor substrate, the method comprising the steps of: (a) forming signal transfer paths between and only between nearby integrated circuit blocks on the same semiconductor substrate, (b) providing control circuits to control signal transfers using said signal transfer paths between nearby integrated circuit blocks wherein said control circuits allow multiple direction signal transfers from a integrated circuit block to a plurality of nearby integrated circuit blocks, and allow transfers between far away integrated circuit blocks through paths comprising a series of said signal transfer paths between nearby integrated circuit blocks, (c) forming a web network of signal transfer paths between a plurality of integrated circuit blocks using said signal transfer paths between nearby circuit blocks where multiple signal transfer paths are available for signal transfers between two points in the integrated circuits on the same wafer. The methods and the structures of the present invention can be illustrated by the practical applications discussed in the following examples.

Application Example: Database Search Engine.

A database search engine is a system used to sort, find, and obtain wanted information out of a large stored data. A classical example is the method to find the right books in a large library. A modern example is the internet search engine used to find interested web sites. To create a relational database, first we need to collect information about resources or documents, determine terms to be indexed; then create a record for each document, and put into index tables in ways convenient for users to search and to obtain needed data. The former process is called gathering process, and the latter is called indexing process. Gathering and indexing processes are usually not timing critical because we only need to update the database once in a while.

After a relational database is established through gathering and indexing processes, users can obtain data through searching processes. Usually the search procedures start by taking a few key words from the user. The search engine takes those key words, then applies them to the index and finds a set of records (called the result set) that satisfies the criteria specified by the user. The search system should have the capability of providing the original resources to the user according to the information in the result set. In this process (called the retrieval process), the system transfers the original document to a local system, where it can be viewed, saved, or printed. For a large database that supports many users simultaneously, the search and retrieval processes can be timing critical.

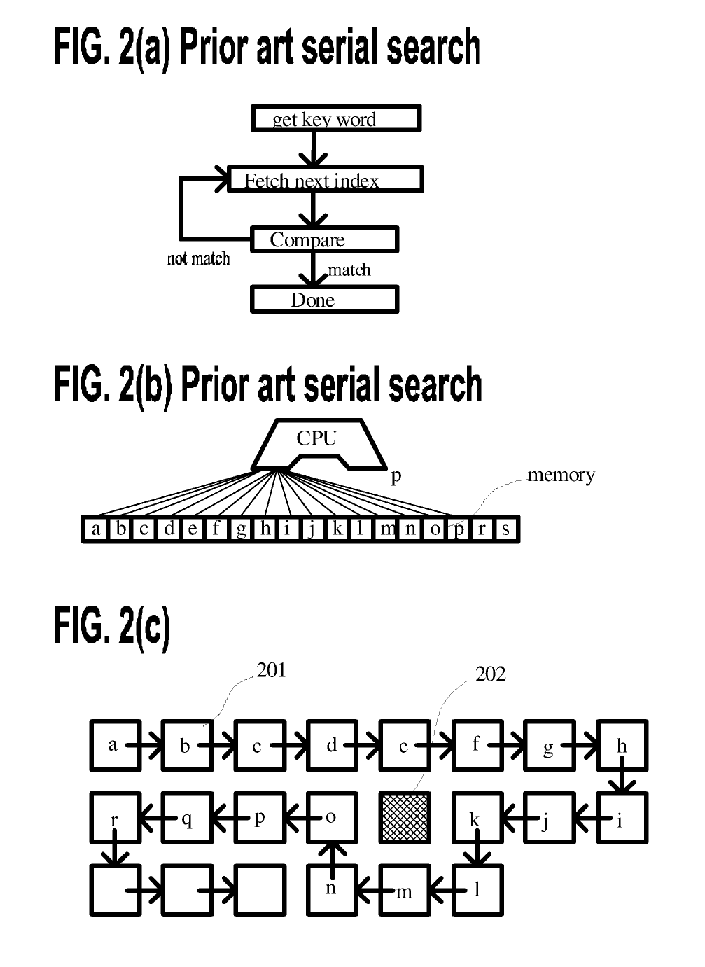

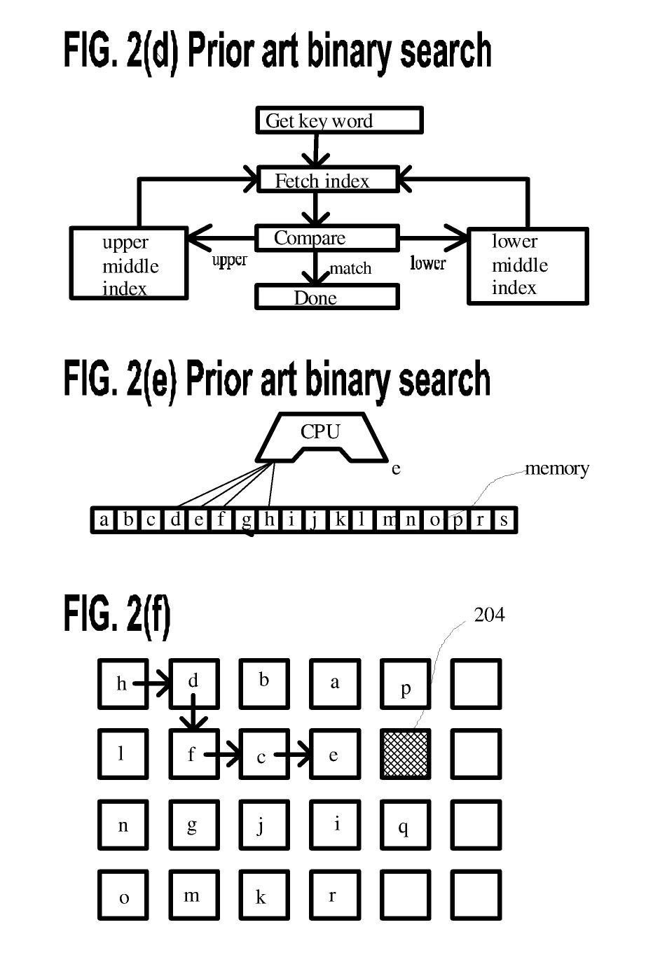

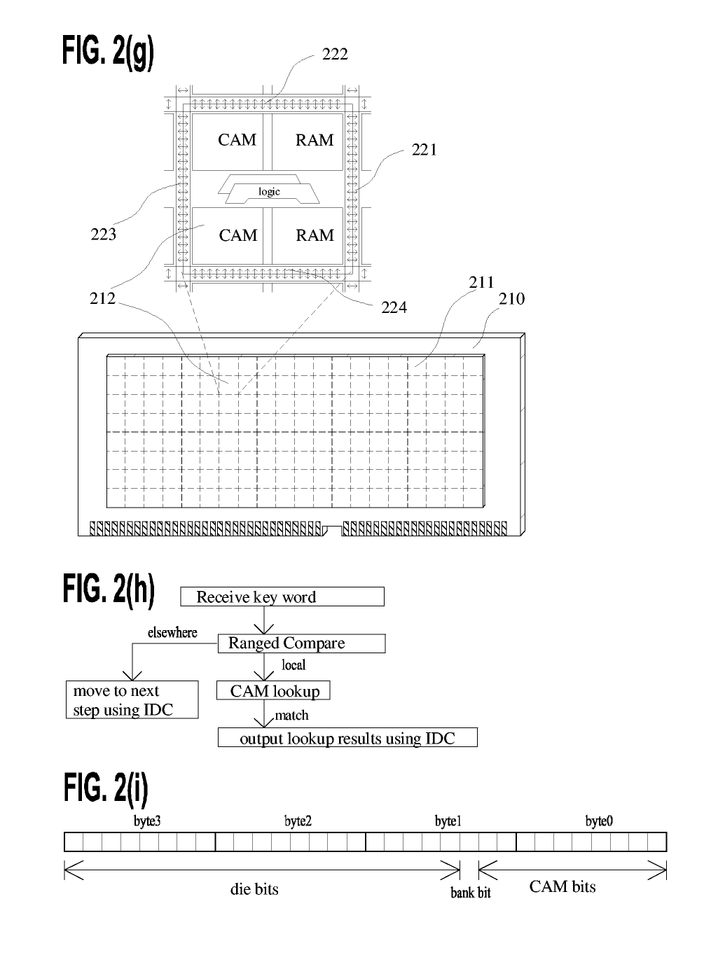

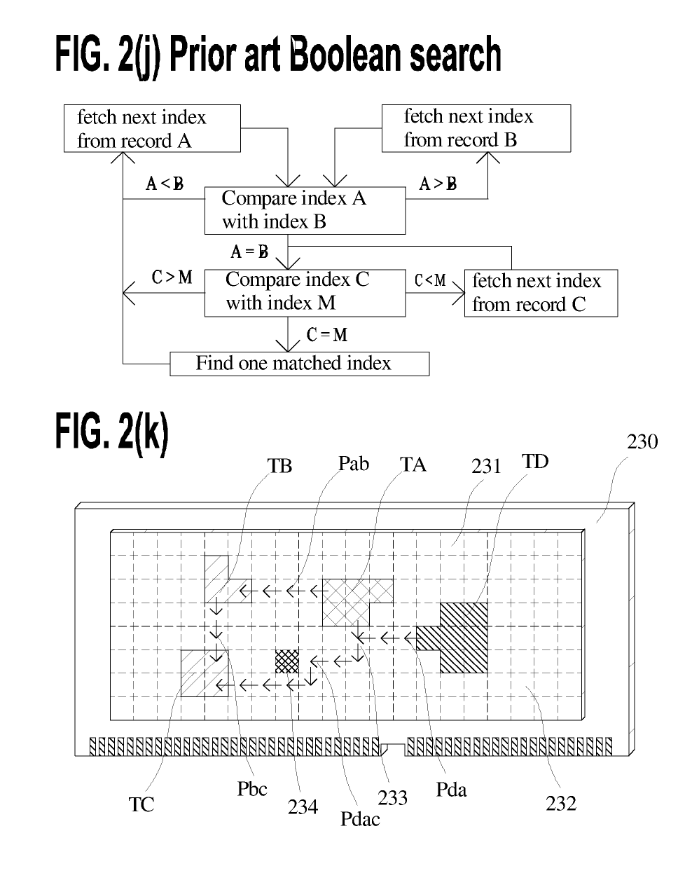

Web-IC of the present invention can provide dramatic performance improvements for database systems as illustrated by the examples in FIGS. 2(a-k). For clarity, over simplified examples are used in the following discussions. Practical applications are by far more complex, but the basic principles are the same as the following simplified examples.

The simplest database search method is serial search. A serial search lookup an index table one by one until a match with the key word is found. Usually the index table has been sorted. FIG. 2(a) is a float chart for one example of prior art serial search. After the user provides a key word, the search engine fetch one index from the index table, and compare with the key word. If a match is found, the job is done; otherwise, the search engine fetches next index in the table for comparison until a match is found or when no match can be found. FIG. 2(b) is a symbolic diagram illustrating the prior art procedures to execute serial search. In this simplified example we assume indexes are in alphabets from “a” to “s”. These indexes are sorted and stored in memory devices. When the user type in key word “p”, a serial search will fetch from the beginning of the index table, starting from “a”. Each fetched index is compared with the key word by a central processing unit (CPU) one by one until a match is found, as illustrated in FIG. 2(b).

FIG. 2(c) shows the symbolic view for a Web-IC of the present invention supporting serial search. The structure of this IC can be similar to the one in FIG. 1(d). The index table is stored in the dice of the IC as illustrated in FIG. 2(c). We can go around a defect die (202) as illustrated in FIG. 2(c). The key word is sent into the first die (storing index “a”) for comparison, if a match is not found, the key word is sent to the next die (storing index “b”) for the next comparison. Such procedure is repeated until a match is found, and the search results are sent out through Web-IC signal transfer.

The search method in FIG. 2(c) is more efficient than the prior art search method in FIG. 2(b). The prior art method in FIG. 2(b) handles one search at a time, while the method in FIG. 2(c) can support multiple searches in parallel. For example, when a key word search finished comparison in die “a” and moved into die “b”, another key word search can start in die “a” in ways similar to pipelined circuits. At maximum usage, the number of parallel search equals the number of comparators in the IC. A large area IC of the present invention can have thousands or more dice so that thousands or more searches can be executed simultaneously. In addition, the prior art method in FIG. 2(b) requires a memory fetch operation for each comparison. Memory operations typically require many clock cycles in prior art systems. For example, a memory operation to the main memory of a computer typically takes more than 100 CPU clocks. The method in FIG. 2(c) requires a Web-IC data transfer for each comparison that can be finished in one CPU clock.

Serial search is simple but it is not efficient to search a large table. Many search mechanisms have been developed to shorten the number of search steps. One of the most common mechanisms is the binary search mechanism illustrated in FIGS. 2(d-e). FIG. 2(d) is a float chart for binary search. A search would start from fetching an index from the middle of a sorted table and compare this middle index with the key word. If there is a match, the job is done. If the key word is found to be in the lower part of the table, the next step is to fetch the index that is at the middle of the lower half of the remaining table for comparison. If the key word is found to be in the upper half of the table, the next step is to fetch the index that is at the middle of the upper half of the remaining table for comparison. Such procedure is repeated until the search is done, as illustrated by the float chart in FIG. 2(d).

FIG. 2(e) is a symbolic diagram illustrating the prior art procedures to execute binary search. In this simplified example we assume indexes are in alphabets from “a” to “s”. These indexes are sorted and stored in memory devices. When the user types in key word “e”, a binary search will fetch “h” from the middle of the index table. The CPU determines key word “e” is at the upper half of the table relative to “h”, so it issues command to fetch the next index “d” from the middle of the remaining upper half. After comparison, the CPU determines key word “e” is at the lower half of the remaining table, and it issues command to fetch the next index “f” from the middle of the remaining lower half. After comparison, the CPU determines key word “e” is at the upper half of the remaining table, and it issues command to fetch the correct index “e” and finished the search. A binary search takes less or equal to n steps to finish searching a table with 2ⁿ indexes. Therefore, it takes much less steps to search for a key word comparing to a serial search.

FIG. 2(f) shows a Web-IC of the present invention supporting binary search. Each functional die stores an index and equipped with logic circuits that determine the location of the next destination depends on key word comparison. For example, we start from die “h” to search for key word “e”. The job would be done if the key word is “h”. If the key word is not “h”, the logic in die “h” will send the key word either to die “d” or to die “I” through inter-dice data transfer for the next comparison. Such procedures are repeated until the key word “e” is found at die “e” through the steps illustrated in FIG. 2(f). Sometimes more than one step of inter-dice transfer is taken after one comparison. We can go around a defect die (204) due to the flexibility provided by Web-IC data transfer methods.

The search method in FIG. 2(f) is more efficient than the prior art search method in FIG. 2(e). The prior art method in FIG. 2(e) handles one search at a time, while the method in FIG. 2(f) can support multiple searches in parallel. In addition, the prior art method in FIG. 2(e) require a memory fetch operation for each comparison. The method in FIG. 2(c) requires one or a few steps of inter-dice data transfer for each comparison that can be finished in one CPU clock.

The above examples in FIGS. 2(a-f) are over-simplified. The actual implementation can be more complicate. For the examples shown in FIGS. 2(c, f), each functional die stores only one simple index. In reality, a functional die is by far more powerful. FIG. 2(g) shows the symbolic view for one functional die (212) in a Web-IC (211) search engine that is mounted on a PCB board (210). In this example, the functional die (212) comprises content addressable memory (CAM) devices that can execute large number of comparisons simultaneously, random access memory (RAM) devices that store data and instructions, Web-IC circuits (221-224) to send and to receive data, and logic circuits (not shown) to determine what to do after each step. One example for the function of the logic circuits is illustrated in FIG. 2(h). When a functional die received a key word for search, it executes a “ranged compare” to determine whether the key word can be found locally within the functional die. If the key word is stored elsewhere, the logic circuits determine the location of the next die, and send the job to the next destination using Web-IC data transfer. If the key word is local, a CAM lookup is executed to find the target index, and the search result is sent out through Web-IC network.

FIG. 2(i) shows one example of an index. In this example, the index has been digitized into a 32 bit (4 bytes) binary number. We assume in each die there are two banks of CAM as shown in FIG. 2(g), while each bank has 1024 (1K) entries. Normally, each CAM entry needs to have 32 bits in order to execute 32-bit index lookup. In this example, we assume all the indexes are sorted before they are stored into CAM. In this way, we only need to store the lower 10 bits (called “CAM bits”) of the index into CAM (plus a valid bit). Another bit, called “bank bit” as shown in FIG. 2(i), is used to distinguish indexes stored in which bank of CAM in the same functional die. We assume that all the indexes stored in the same functional die (212) share the same or a few sets of upper 21 bits (called “die bits”). It is not necessary to store these die bits into CAM; storing them in registers is by far more efficient. When a key word is sent into a functional die (212) for comparison, we should compare the die bits first. If all die bits match, we can execute CAM lookup to one of the bank determined by the bank bit. The lookup results are then sent out to finish the job. If there is no match in the die bits, the logic circuits can determine the destination for the next step, and send the key word to the next destination through signal network.

A database search engine of the present invention is by far more powerful than prior art search engines. The performance differences between prior art search engines and the search engines of the present invention can be estimated using practical examples. Assume we want to execute key word search in an index table that has 8 million indexes. Each index has been digitized into 32-bit binary numbers. The speed of a prior art search engine in FIG. 2(e) is limited by the speed to fetch data from storage devices. Assume the search engine store all 8 million indexes in a 32 Mega byte DRAM module that can operate at a random access rate at an average rate of 200 million indexes per second. For a binary search, it takes maximum 23 steps to search 8 million indexes, while each step requires a compare and a random data fetch. The average search rate is therefore around 10 million searches per second. In comparison, assume the Web-IC (211) in FIG. 2(g) is 40 mm high and 100 mm wide, and each functional die (212) is 1 mm high and 1 mm wide. That means there are 4,000 functional dice on the module. Assume each functional die (212) comprises 2 banks of CAM while each bank comprises 1 K entries. The total number of entries stored in a single module is about 8 million indexes. That means we can store all 8 million entries of the index table into the Web-IC (211). A binary search will take at most 12 steps to find the right die that contains the index, and it takes another step to lookup the CAM in the functional die. Assuming the clock rate is also at 4 billion operations per second, it will take about 3 nanoseconds (ns) to finish one search. In addition, each functional die can handle a separated search without waiting for previous search to be finished. That means we can execute 4 billion searches per second. We also can send multiple searches into the Web-IC through different locations and execute them in parallel. Assuming each Web-IC (211) can accept 4 search requests per clock, it is therefore able to execute 16 billion searches per second. The peak search rate is therefore more than 1000 times higher than the prior art search engine. If we need higher search rate or larger index tables, we have the options to use larger Web-IC (because we no longer have die size limitation) or more Web-IC. Such dramatic improvement in search rate will allow search engines to use more sophisticate search mechanisms to improve the quality of search results. A low cost Web-IC module will be able to support jobs that require high cost servers in current art systems.

Many searches require Boolean operations on multiple key words. For example, if we want to look for a person called Thomas Smith who lives in Washington, we want to search for (Thomas AND Smith AND Washington). FIG. 2( ) is a flow chart for prior art method to execute a Boolean search (A and B and C). We assume all three records (A, B, C) have been digitized and sorted during the gathering and indexing procedures. The prior art method in FIG. 2(j) fetches one index from record A, fetches another index from record B, and executes a comparison between the two fetched indexes. If A>B, then the next index in record B is fetched for another comparison. If A<B, then the next index in record A is fetched for another comparison. If there is a match as A=B=M, then the next index in record C is fetched to be compared with M. If C<M, then the next index in record C is fetched for another comparison. If C>M, that means there is no match between C and M, the procedure goes back to find the next match between A and B records. If C=M, an index that meets the requirement is found, the procedure continue to find the next matched index. Such prior art Boolean operation takes a large number of memory fetching and logic operations. It is time consuming for prior art methods.

FIG. 2(k) illustrates a method to uses a Web-IC (231) of the present invention to execute the same Boolean operation (A and B and C). This Web-IC is mounted on a PCB (230). For the example in FIG. 2(k), the indexes in record A has been sorted and stored into the Web-IC (231) in an area (TA) occupying 5 dice; the indexes in record B has been sorted and stored into the Web-IC (231) in an area (TB) occupying 3 dice; and the indexes in record C has been sorted and stored into the Web-IC (231) in an area (TC) occupying 4 dice. All these record (TA, TB, TC) are ready for high performance search using functional dice similar to those shown in FIG. 2(g). To execute the Boolean operation (A and B and C), indexes in TA are sent through an inter-dice transfer path (Pab) to area TB for index searches, the matched indexes are then sent through another inter-dice data transfer path (Pbc) to area TC for index searches. Each comparison takes less than 10 inter-dice signal transfer cycles, and the searching and fetching processes are executed in parallel. The overall performance can be more than 1000 times better than prior art methods. In addition, the Web-IC (231) also can execute other Boolean operations in parallel. For example, another user requests another Boolean operation [(D or A) and C]. We assume the indexes in record D have sorted and stored in area TD that comprises 7 dice as shown in FIG. 2(k). In parallel to the other Boolean operation, the indexes in area TD are sent to a functional die (233) through an inter-dice data transfer path (Pda), and the indexes in area TA is also sent to the same die (233) to execute Boolean OR operation. The results are then sent to area TC through another inter-dice signal transfer path (Pdac) to area TC for index searches as Boolean AND operations. Both Boolean operations can be executed in parallel to many other operations by the same Web-IC (231), reaching extremely high performance.

After we find the indexes of the data using search methods described in previous sections, the next step is retrieving data from mass storage devices. Data is usually stored in mass storage devices such as tapes, compact disks (CD), hard disks, or solid state storage devices. The performance of the retrieving process is determined by the speed of the mass storage devices. Solid state storage devices are typically more than 10 times faster than mechanical storage devices, but they are also typically much more expensive. In addition, the storage capacities of solid state devices are also typically smaller than mechanical storage devices. The present invention can help to improve the cost efficiency and the storage capacity of solid state storage devices, and therefore improve database retrieving performance by allowing database systems to use solid state storages devices more often than prior art database systems.

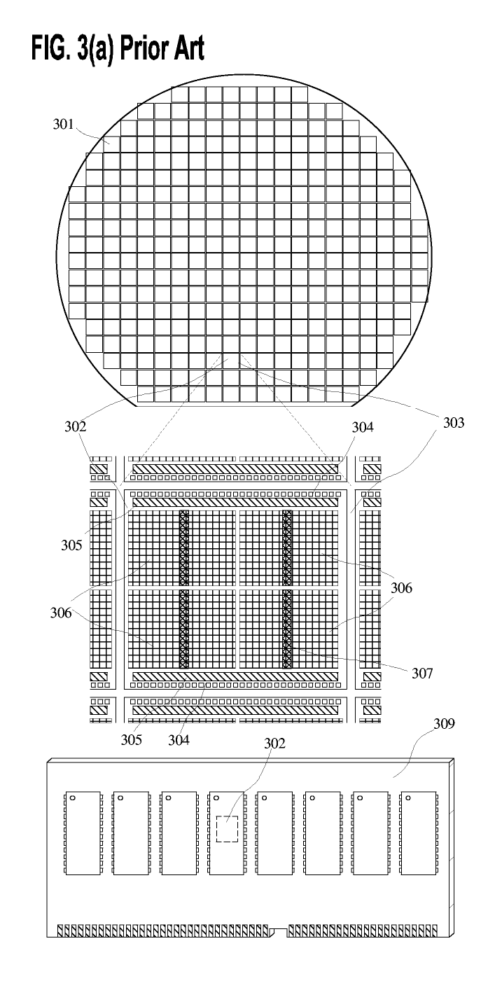

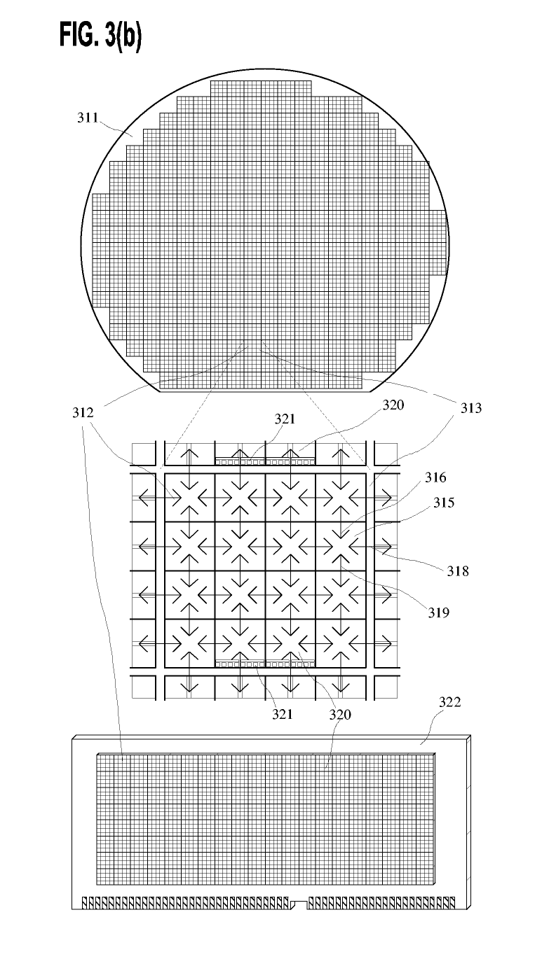

FIG. 3(a) shows the structures of a wafer (301) for prior art solid state storage IC devices, a magnified symbolic diagram showing the structures for one die (302) on the wafer, and the structures when the die (302) is placed in a PCB module (309). This wafer (301) comprises a plurality of dice (302) of prior art memory IC. Well known examples for memory IC are NAND FLASH EPROM or dynamic random access memory (DRAM). Magnified symbolic structures for one die (302) of the memory IC show a typical structure that comprises memory arrays (306), memory decoders (307), I/O circuits (305), and bounding pads (304). For a prior art wafer, each die (302) is isolated from other dice and separated from nearby dice by scribe lanes (303), and there are no signal connections between nearby dice crossing the die boundaries. After fabrication and testing are completed, the wafer is scribed to separate the individual IC devices. Each separated die (302) is packaged into chips, and the chips are mounted on printed circuit board (309) with other chips to form a storage device module as illustrated in FIG. 3(a).

FIG. 3(b) shows the structures of a wafer (311) for solid state storage IC devices of the present invention, magnified symbolic views for dice (312) on the wafer, and an example when a Web-IC cut from the wafer (311) is placed on a PCB (322). This wafer (311) comprises a plurality of separable dice (312) that are surrounded by scribe lanes (313). In this example, each separable die comprises 16 functional dice (315) as illustrated by the magnified symbolic diagram in FIG. 3(b). Each functional die comprises memory arrays and decoders similar to prior art IC except that each functional die (315) is typically much smaller than prior art dice (302). We can have more than one type of functional dice on the wafer (311). For example, we can have two I/O dice (320) equipped with I/O pads (321) for every 16 functional dice as shown in the magnified picture in FIG. 3(b). Each functional die has Web-IC signal transfer circuits (316, 318, 319), represented by arrows in FIG. 3(b). These Web-IC signals form a network of communication paths. As discussed in previous section, a Web-IC arranged in this way does not have die size limitation because we can bypass failed circuits using the Web-IC communication network. We can cut a big piece of the wafer and mounted it on a printed circuit board (322) as shown in FIG. 3(b). The inter-dice communication network will allow us to bypass failed circuits no matter the failures are caused by IC manufactures or PCB assembly procedures.

The Web-IC in FIG. 3(b) is more cost efficient than the prior art solid state storage device in FIG. 3(a). This cost differences can be demonstrated by cost analysis of practical examples. A memory device needs to have supporting circuits such as decoders, I/O circuits, and I/O pads, to support its operation. The areas occupied by those supporting circuit are considered overheads because they reduce the percentage of silicon areas occupied by memory arrays. The ratio of the area occupied by memory cells relative to total area is called “array efficiency” in the art of memory IC design. Besides the size of memory cells, array efficiency is one of the most important factors for cost efficiency of solid state storage devices. Prior art IC has one die per chip; each die must have a complete set of peripheral circuits to support its operations. Therefore, the array efficiency of prior art memory devices typically increases with the total storage capacity in a die. In order to reduce overhead, it is desirable to increase the capacity of each individual prior art IC. However, increasing capacity will reduce yield exponentially for prior art IC. IC designers need to find an optimum size to achieve minimum cost per bit. For prior art IC, the die size for optimum cost efficiency is typically around 1 cm² with ˜50% array efficiency and ˜80% yield rate. That is why almost all commercial IC memory devices have similar die sizes around 1 cm². Besides array efficiency and yield considerations, there are other factors such as testing costs and packaging costs that influences the cost of prior art IC. Using DRAM as an example, assuming an 8 inch wafer cost ˜$800/wafer can have 300 chips (around 1 cm² per chip). If the yield is ˜80%, the cost is ˜$3.3 per chip before testing and packaging. If the testing and packaging cost is around $1 per chip, the overall cost per chip is around $4.3. If the capacity of each chip is 512 Mb (million bits) or 64 MB (million bytes), the cost is estimated to be ˜$0.067/MB.

For a Web-IC of the present invention, we no longer need to have a complete set of I/O circuits in a small die. A large area Web-IC can share a set of I/O circuits to achieve better array efficiency. The typical array efficiency for Web-IC used as storage device is therefore better than prior art IC, such as 75%. In addition, Web-IC comprises a large number of small dice, and we can bypass bad dice to achieve high yield such as 98%. We also can use testing methods described in the references (P222, A836, A921) to save testing costs. Assuming we use the same manufacture technology to fabricate Web-IC in FIG. 3(b), an 8 inch wafer cost ˜$800/wafer. The overall cost is calculated to be ˜$0.03/MB, achieving a 50% cost reduction relative to prior art memory devices. Similar cost saving can be achieved for NAND FLASH EPROM. That means a database system can double the capacity of the solid state storage devices it equipped for a given budget. Resulting in improved performance because more retrieving processes can be executed in fast solid state storage devices. Beside cost advantages, the Web-IC has the flexibility to adjust capacity and data width by adjusting the number of separable dice in a module. The data bandwidth of Web-IC is also by far higher than prior art storage devices due to the high bandwidth inter-dice transfer methods.

While specific embodiments of the invention have been illustrated and described herein, other modifications and changes will occur to those skilled in the art. It should be understood that these particular examples are for demonstration only and are not intended as limitations on the present invention. The above examples for applications of Web-IC of the present invention in database operations are over simplified symbolic illustrations. A wide variety of implementations will be developed upon disclosure of the present invention. The inter-dice signal lines or Web-IC signal paths shown in the above figures are not drawn to scale. In reality, we can have hundreds or thousands of Web-IC connections between nearby dice; it is not practical to draw those signal paths according to their actual scale. That is why we used symbolic drawing to represent the Web-IC paths. In the following discussions, the Web-IC connection lines will not be shown in our figures, and we will assume the reader understand that there are Web-IC lines arranged in web structures for all Web-IC in our examples.

Application Example: Routers.

Routers are critical hardware needed to support communication systems. A router is a device that determines the next network point to which a packet of data should be forwarded toward its destination based on its current understanding of the state of the networks it is connected to. A router creates and/or maintains a table of the available routes and their conditions and uses this information along with pre-defined algorithms to determine the best route for a given packet. Typically, a packet of data may travel through a plurality of network points with routers before arriving at its destination. In many ways, the structures and the functions of a router are very similar to database search engines. Both applications arrange information into lookup tables, and search the lookup table to determine the target locations of data.

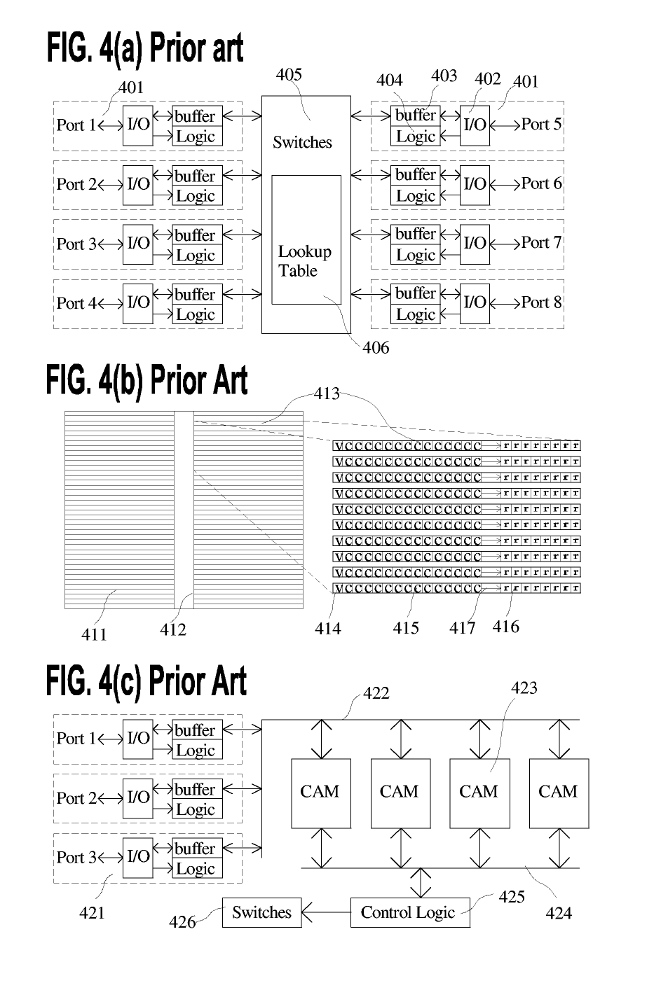

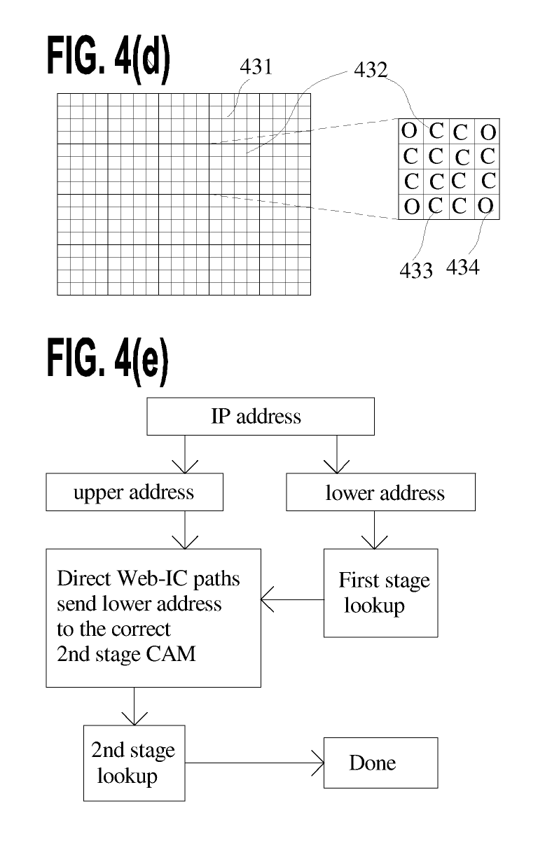

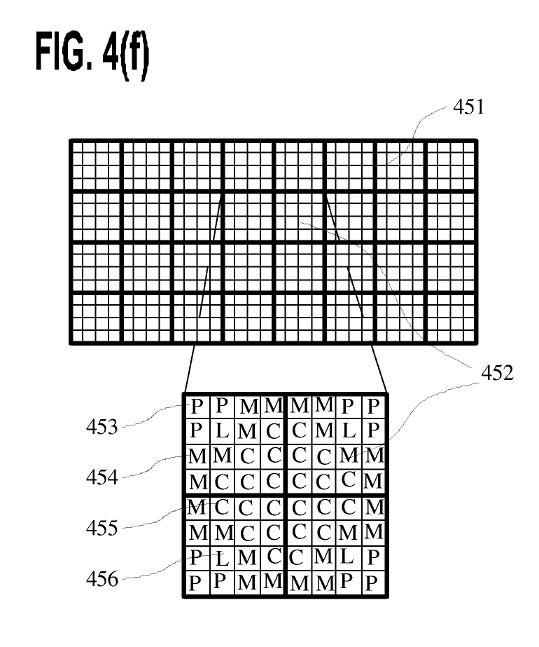

FIG. 4(a) is the symbolic block diagram for one example of a prior art router. The router in this example has 8 ports. A port (401) is an interface to another network. Popular examples of networking ports are Ethernet twisted pair local area network (LAN) interface, IEEE 802.11 wireless LAN interface, Digital Subscriber Line (DSL) wide area network (WAN) interface, cable modem WAN interface, telephone modem WAN interface, and optical fiber WAN interface. Each port (401) have supporting circuits such as I/O circuits (402) that convert input/output signals to proper formats between the router and the external networks, buffers (403) as temporary data storage, and control logic circuits (404) executing operations such as timing control and authentic calculations. The core circuits of a router are switches (405) that forward data sent from one port to another port based on the status of related networks stored in lookup tables (406). The lookup tables are typically the most important components in determining the performance and the cost of prior art routers.

The simplest way to implement the lookup table is to use a memory device such as a high speed static random access memory (SRAM) to store the status of different clients. The lookup procedure is executed by reading the table content one by one until finding the right information, in ways similar to database serial search. When the lookup table is large, this method is too slow. A typical solution to improve lookup efficiency is to use content addressable memory (CAM). FIG. 4(b) illustrates the basic structures of a prior art CAM device. A typical CAM (411) device comprises a decoder (412) and a plurality of entries (413). Magnified diagram in FIG. 4(b) shows the symbolic structures of CAM entries (413). Each CAM entry (413) comprises a valid bit (414) (marked “v” in FIG. 4(b)), a plurality of CAM memory cells (415) (market “c” in FIG. 4(b)), and a plurality of data storage memory cells (416) (market “r” in FIG. 4(b)). The valid bit (413) indicated whether the information stored in the entry is valid or not. The CAM memory cells (415) have two functions: they are memory cells that can store the value of an address, and they also support the function of a comparator to compare the stored address with lookup address. The storage memory cells (416) store a set of data associated with the address stored in the CAM cells. During a lookup operation, if the lookup address matches the stored address in the entry (413), the entry will report a “hit”, and triggers an entry select signal (417) to put the data stored in the storage cells (416) into output bus. For an IP address that has 32 bits, there are 2³²˜4 billion possible combinations. If each entry has 1 valid bit, 32 CAM cells, and 16 storage cells, we will need a CAM device with a capacity of ˜200 billion bits. It is not practical to build such a big device using prior art IC. Typically we only store recently used addresses into CAM. A prior art CAM device typically have less than one million (1M) entries so that it can fit into a die size around 1 cm² to have reasonable yield. One solution to increase effective CAM capacity is to use ternary CAM cells. A ternary CAM cell supports three logic states (“0”, “1”, and “don't care”). The third state—“don't care”—allows multiple IP addresses to share the same CAM entry. The size of a ternary CAM cell is nearly twice as large as the size of a binary CAM cell, but may be more cost effective considering effective capacity. CAM devices allow simultaneous lookup to compare an external address to all the addresses stored in all the entries. Typically only one entry can have a “hit”, and the data stored in the hit entry are sent out to determine how to handle the data associated with the lookup address. If a new address can not be found in CAM (a “miss”), the supporting logic will choose an empty CAM entry or kick out an occupied CAM entry to put the information related to the new address into CAM. FIG. 4(c) is a block diagram for a prior art router that uses 4 CAM (423) devices to support address lookup operations. When a data packet reaches one of the ports (421), the destination IP address is extracted from the header in the data packet, and send to the CAM devices (423) through address bus (422). If each CAM device (423) comprises 256K entries. The example in FIG. 4(c) will be able to support simultaneous address lookup of 1M entries. The results of address lookup are sent to control logic circuits (425) through another bus (424). The control logic circuits (425) determine how to handle the data packet based on the results of CAM lookup to control the router switches (426). Typically the CAM address bus operates at a frequency around 200 MHZ (million cycle per second), and a CAM lookup typically takes ˜4 clock cycles. The router in FIG. 4(c) is therefore able to support 5×10¹³ IP address lookups per second. It is very clear that CAM devices are by far more efficient than SRAM devices as lookup table because CAM devices support simultaneous lookup in all entries. In the mean time, CAM is by far more expensive then SRAM. For power consideration, CAM is extremely inefficient because we can turn on millions of entries to obtain the data from one entry.

Most of the disadvantages of prior art CAM devices can be removed if we arrange CAM devices in Web-IC architecture. FIG. 4(d) shows a Web-IC (413) comprises large number of CAM functional dice (432) arranged in Web-IC architecture. As usual, all the functional dice (432) are equipped with Web-IC signal lines to form a web of data transfer paths (not shown). FIG. 4(d) also shows a magnified symbolic view for one of the separable die in the Web-IC (431) that comprises 12 CAM dice (433) (marked by “C” in FIG. 4(d)), and 4 I/O dice (434) (marked by “O” in FIG. 4(d)). The CAM dice (433) have the same structures as prior art CAM devices shown in FIG. 4(b) except that its area is typically much smaller than prior CAM products and that it communicates with other functional dice with Web-IC signal paths so that it does not need any I/O pads. The I/O dice (434) also supports CAM functions and Web-IC data transfer functions; in addition, the I/O dice (434) are equipped with I/O pads to support communication with external signals. As usual, each I/O die does not need to have a full set of I/O pads because we can combine multiple I/O dice to support a single interface.

The advantages of the Web-IC in FIG. 4(d) can be understood by practical examples. Considering the situation when we want to support simultaneous lookup of 4M entries of 32-bit IP address lookup with 16 data bit associated with each entry. For the prior art CAM in FIG. 4(b) to have 4M entries, it needs to have 4M valid bits, 128M CAM bits, and 64M data bits. In addition, it needs to have all the supporting circuits and a complete set of I/O pads. It is estimated that the die size of the prior art devices will be as large as 700 mm² even when we use the most advanced 65 nm IC manufacture technology to build it. The yield will be very close to zero for prior art IC at such large die size. Even if one can build such a large prior art IC, the prior art IC will be very slow due to RC delay, and it will consume unsupportable large power while simultaneously turning on all 4 million entries to lookup one address.

For a Web-IC CAM device, we can use the same “ranged sort” methods as discussed in applications of database search engine. Another method is a “multiple stage lookup” as illustrated by the flow chart in FIG. 4(e). A “multiple stage lookup” divides an IP address into several sections, and execute one address lookup by multiple lookups of part of the address. For prior art CAM devices, multiple stage lookup usually will slow down the lookup procedures because of the difficulty in moving data around in long distance. For Web-IC CAM devices, multiple stage lookup is ideal because of its architecture. FIG. 4(e) is a flow charge for an example of a two-stage lookup. An IP address is separated into two sections—upper address and lower address. The number of bits in these two sections does not need to be the same; they can have overlapped bits; and the choice in address bits does not need to be sequential. The upper address is sent to a CAM device for the first stage lookup. The results of the first stage lookup direct the movements of the lower address to find the location of the correct CAM device for the second stage lookup. The results of the second stage lookup provide the control data as a single stage lookup. We can use the same CAM dice to execute both the first stage and the second stage lookups. We also can use different CAM dices specialized for multiple stage lookups. For example, we can use the type “O” (434) dice in FIG. 4(d) for the first stage lookup, and use the type “C” (433) dice in FIG. 4(d) for the second stage lookup. For the simplest case, if we assume a 32 bit IP address is divided equally into two sets of 16 bit address, and each functional die (433) of a Web-IC CAM comprises 16K entries. Each entry in the CAM functional die (433) needs to have one valid bit, 16 CAM cells, and 16 data storage memory cells. There will be 16K valid bits, 256K CAM cells, and 256K memory cells in one functional die (433). Using the same IC manufacture technology (65 nm) as the prior art example to build such die, the die area will be smaller than 1 mm². Such small area IC can operate at high frequency (higher than 1 GHZ) while achieving high yield (˜99%). The Web-IC data transfer through nearby die at such small die size can easily operate at high frequency (e.g. 4 GHZ). To support lookup of 4M entries, we need a few first stage Web-IC CAM dice and 256 second stage Web-IC CAM dice (433). Using the two stage lookup shown in FIG. 4(e), the first stage lookup determines the location of the second stage CAM die, and it will take less than 16 inter-dice signal transfers to send the lower address to the target second stage CAM die for the second stage lookup. As usual, we can bypass dice that are not available using Web-IC data transfer methods. The results of the second stage lookup will take less than 16 steps of Web-IC data transfer to reach I/O ports. The overall lookup time is equal to 2 CAM lookup time of small (16K) CAM, plus less than 32 steps of Web-IC data transfer; the lookup time is shorter than 10 ns. As usual, we can pipeline multiple address lookups, and we can execute multiple lookups simultaneously using Web-IC architecture. Assuming we have 8 first-stage CAM dice in the Web-IC, we will be able to execute 8 billion address lookups to 8M entries per second (equivalent to 64×1 015 lookups/second), and finish each IP address in ns latency, reaching a performance level that is not imaginable for prior art CAM devices. In addition, each IP address lookup only turn on two small (16K entries) CAM devices instead of a huge 4M entries CAM, plus the fact that we do not need external bus to transfer data, the power consumption is three orders of magnitudes lower than equivalent prior art CAM devices. The total area of such Web-IC CAM device is ˜300 mm²; the cost is estimated to be ˜$10. If we need even better performance or lower power, Web-IC architecture provides the flexibility to use more dice or use smaller dice to achieve those goals.

A prior art router is a complex system. One typical example for prior art router is CISCO Catalyst 6500. Ethernet module 720. The router module supports 48. Ethernet ports; each port has a 1.3 MB buffer and consumes 7 Watts of power; the router module comprises hundreds of IC chips and electrical components. A simpler prior art example is NETGEAR WGR614 wireless router that supports 4. Ethernet ports, one DSL port, and one 802.11 wireless port. The router fits into a small box. The most complex prior art routers are used as internet back bone; those routers can be as complex as super computers.

All the function of prior art routers can be supported by Web-IC of the present invention at much lower cost, consuming much lower power, while achieving better performance. One design of a Web-IC router is illustrated by the symbolic diagram in FIG. 4(f). This Web-IC (451) comprises large number of functional dice. A magnified symbolic diagram in FIG. 4(b) shows the arrangement of functional dice in a portion of the Web-IC (451). Functional dice marked by “P” in FIG. 4(b) are port interface dice (453) that provide interface circuits to external ports. Functional dice marked by “L” in FIG. 4(b) are logic dice (456) that support logic operations. Functional dice marked by “M” in FIG. 4(b) are memory modules (454) working as data storage devices or buffers. Functional dice marked by “C” in FIG. 4(b) are CAM modules (455) supporting address lookup operations. Detailed structures of those functional dice are well-known to the art of circuit design so that there is no need to provide further details in the present invention. Prior art IC can not have so many circuits on one chip because the die size will be too big to have reasonable yield, and its performance will be terrible. Therefore, prior art router uses many chips to provide the router functions. For Web-IC, all of these dice are supported by Web-IC signal transfer networks (not shown) so that we can transfer signals between them with high bandwidth, and we can achieve high yield by bypassing unavailable circuits. The Web-IC architecture makes it possible to put the whole router system in a single IC.

While specific embodiments of the invention have been illustrated and described herein, other modifications and changes will occur to those skilled in the art. It should be understood that these particular examples are for demonstration only and are not intended as a limitation on the present invention. For example, the IP address does not need to be 32 bits; it can have any number of bits. For another example, the flow chart in FIG. 4(e) illustrates two stage CAM lookup while similar methods can be applied to three stage lookup or multiple stage lookup. It is also a good practice to place a CAM die that stores the most recent lookup results around a port die. The data packets come from a port have high chance to have the same destination as recently transferred data packets. Instead of executing a complete multiple-stage address lookup every time, it is a good practice to lookup a small CAM or lookup table to see if the destination is the same as one of the recent lookup, and shorten the lookup procedures. These and many other variations will be obvious to those familiar with the art of IC design, upon disclosure of the present invention. Not all lookups must be executed using CAM devices; we also can support RAM lookups. CAM devices allow parallel lookup to achieve high performance, but it is more expansive than RAM. Using multiple stage lookups and Web-IC architecture, RAM lookups (serial or binary) can be executed with much better efficiency than prior art methods. Besides cost advantages, RAM lookup also allow more flexibilities to execute complex calculations. The structures of Web-IC supporting RAM lookups can be the same as the Web-IC supporting computer applications as discussed in the next application examples. We certainly can combine CAM and RAM lookups in multiple stage lookup operations. For example, we can execute first stage lookups using CAM devices, while executing final stage lookups using RAM binary lookup.

Application Example: Computers.

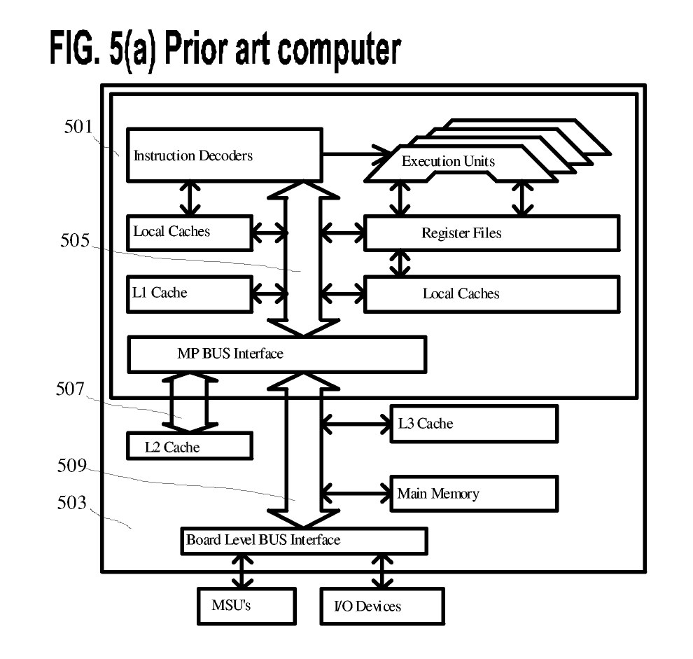

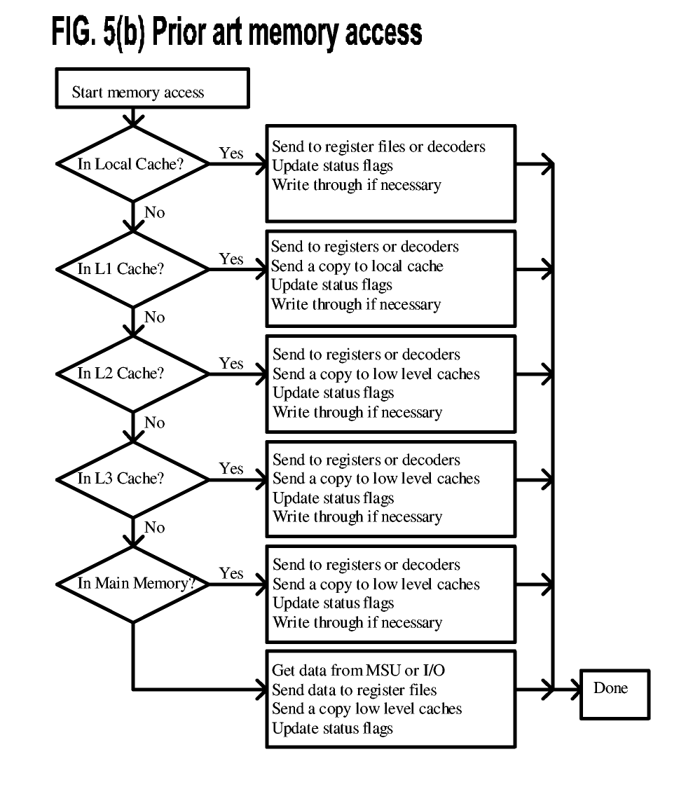

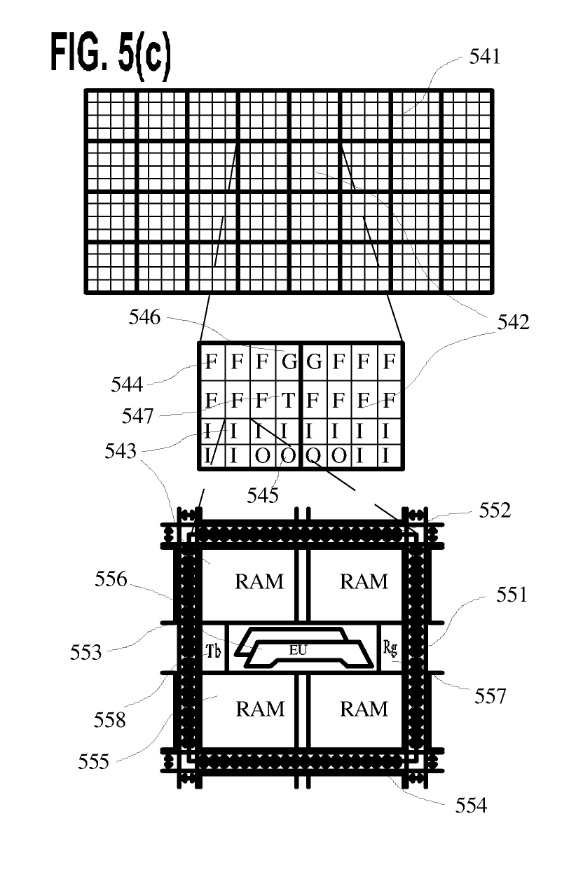

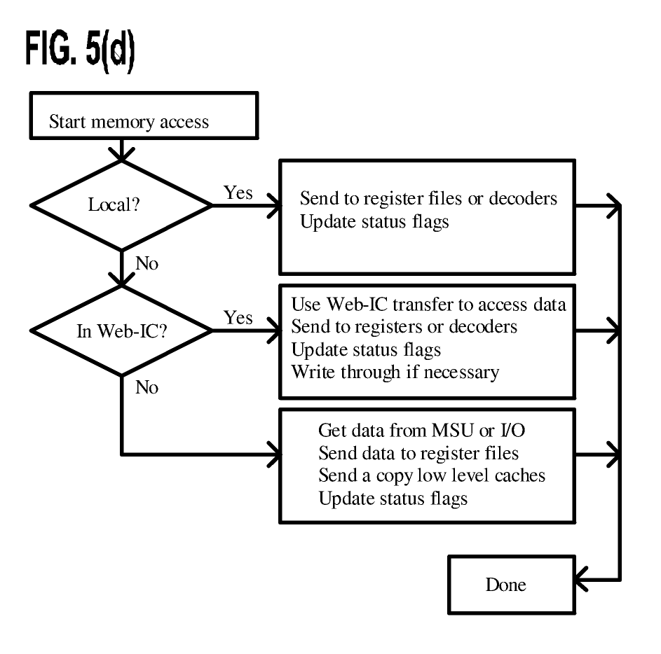

At the early history of computer design, the central processing unit (CPU) executing calculations and logic operations was the dominating unit in a computer. All the other “supporting circuits” bring in needed information to support the operations of CPU. That thinking no longer matches the reality of advanced technologies. Current art CPUs can execute billions of instructions per second. Unfortunately, the supporting storage devices are not able to provide instructions and data fast enough to fully utilize CPUs. Those supporting circuits are dominating the cost and the performance of current art computer systems. However, current art computers still centers around the historical thinking. We are using extremely complex data transfer systems to bring information to serve a few execution units. The computer architectures developed based on the out-of-date historical thinking caused performance bottlenecks and created extremely complex control logic circuits. To reduce the bottleneck caused by storage devices, current art computers rely on a hierarchical memory structure as illustrated by the simplified system block diagram in FIG. 5(a). A typical computer system is equipped with mass storage units (MSUs) such as hard disk, floppy disk, or compact disk read only memory (CDROM) to store software programs and data. The system also needs input/output (I/O) devices such as key board, mouse, monitor, parallel port, series port, or networking card to communicate with the outside world. Most of the computer activities are controlled by a mother board (503). The mother board has many components such as a microprocessor (501), main memory, level two (L2) and level three (L3) cache memory, and a board level BUS interface. The main memory, L3 cache, and the microprocessor communicate with a board level bus (509). The L2 cache typically has its own backside bus (507) communication with the microprocessor (501). The microprocessors (501) are usually considered as the CPU, but they actually comprise multiple layers of memory devices. At the center of the microprocessor (501) are a number of execution units (EUs) that execute computer instructions. Examples for execution units are arithmetic logic units (ALUs), floating point units (FPUs), and address generation units (AGUs). These EUs follow instructions provided by the instruction decoder, and operate on data provided from register files. Instructions and data are provided by the MSUs or I/O devices. Current art ALUs can operate at 4 GHZ (billion cycles per seconds) per pipeline, while a hard disk access time is around 10 milliseconds. Since MSUs and I/O devices are by far slower than the execution units, the only way to reach high performance is to keep copies of instructions and data close to the execution units. That is why prior art computers need to have local caches, level 1 (L1) cache, and complex hierarchical storage devices.

FIG. 5(b) is a float chart that shows the procedures for a memory access of a typical prior art computer system. When the execution units need instructions or data, the system must execute memory access to get the information. The basic concept is to look for the needed information from the fastest memory device. If the information can be found in local cache, the results are sent to register files or instruction decoders directly, followed by some book keeping activities such as updating flags and updating higher level storage devices. If the information is not stored in local cache, we need to look into L1 cache. If the information can be found in L1 cache, the results are sent to register files or instruction decoders directly, followed by some book keeping activities such as updating flags and updating higher level storage devices. A copy of the information, including nearby data, are also stored into local cache so that future memory access is likely to hit local cache. If the information is not stored in L1 cache, we need to look into L2 cache. If the information can be found in L2 cache, the results are sent to register files or instruction decoders directly, followed by some book keeping activities such as updating flags and updating higher level storage devices. A copy of the information, including nearby data, are also stored into local cache and L1 cache so that future memory access is likely to hit lower level caches. If the information is not stored in L2 cache, we need to look into L3 cache. If the information can be found in L3 cache, the results are sent to register files or instruction decoders directly, followed by some book keeping activities such as updating flags and updating higher level storage devices. A copy of the information, including nearby data, are also stored into lower level caches so that future memory access is likely to hit lower level caches. If the information is not stored in L3 cache, we need to look into main memory. If the information can be found in main memory, the results are sent to register files or instruction decoders directly, followed by some book keeping activities such as updating flags and updating higher level storage devices. A copy of the information, including nearby data, are also stored into lower level caches so that future memory access is likely to hit lower level caches. If the information is not stored in main memory, we need to get the information for MSU or I/O devices. The results are sent to register files or instruction decoders directly, followed by some book keeping activities such as updating flags. A copy of the information, including nearby data, are also stored into all the memory devices so that we can avoid these slow devices as much as possible in the future. The way for a current art cache memory to determine whether a copy of data is stored in a particular cache memory is to store the addresses of all its data into a lookup table called “TAG memory”. This TAG memory also stores book keeping parameters based on memory coherent requirements. The content of the TAG is compared with the address of a new memory access in order to determine whether the data is already stored in the cache. The look up procedures into different levels of TAG memory is the most notorious bottleneck limiting the performance of current art computer systems.

Most of time, computer programs tend to loop around small sections of instructions repeatedly. This computer operation principle is called “principle of locality” in the art of computer science. The principle of locality assumes that the information needed by execution units can be provided by low level caches most of time. Low level caches can operate at pretty high speed. For example, a current art local cache can have access time around 1 ns. The access time for L1 cache is typically a few ns. The speed of the storage device gets worse as we go to higher level devices, but we don't need to use them very often due to principle of locality. This method of saving small copies of data at high speed high cost devices while keeping bigger copies of data at lower speed lower cost devices allows current art computer systems to have high performance at reasonable cost. However, the data transfer mechanism becomes extremely complex. When there are so many copies of the same data stored at various places simultaneously, we need complex control logic to assure data coherence. Each storage device has its own interface, operates at its own speed, while following its own interface protocols; transferring data efficiently between them require highly sophisticate control circuits. That is the major reason why current art microprocessors are so complex; they can have hundreds of million transistors. Typically, 40-80% of microprocessor chip areas would be occupied by memory devices used as caches or buffers; 20-40% of the areas are occupied by the logic circuits and data paths used to control data transfer from the memory devices to execution units. The areas occupied by execution units are typically negligible. In other words, the performance, power consumption, and cost of current art microprocessors are determined by how you store and transfer data. The designs of the execution units are relatively unimportant.

Prior art computers rely on principle of locality to achieve high performance. However, principle of locality does not work for all applications. For example, using microprocessors to control graphic activities is very inefficient because graphic activities loop around a big memory block called “frame buffer”. The frame buffer is typically larger than cache devices in prior art computer systems so that principle of locality is not applicable for graphic displays. That is why computer systems typically equipped with specialized graphic control IC and graphic memories to support high quality displays. Another example is for scientific calculations working on large vectors or matrixes. For example, considering the case when we want to execute a vector calculation
C(i)=A(i)+B(i), EQ(1)
where i is an integer (i=1, 2, 3, 4, . . . , N), while C(i), A(i), and B(i) are vectors with N elements. If N is very large, the software to calculate EQ(1) is a big loop require large number of memory accesses that can not be executed efficiently relying on principle of locality.

Super computers are the prior art solution to execute large vector calculations such as EQ(1). The computer system shown in FIG. 5(a) is a “scalar machine”. From software point of view, a scalar machine executes one instruction at a time. In reality, current art CPUs often have parallel pipelines to execute multiple (typically 2-8) instructions in parallel. Such CPUs with small number of parallel execution capabilities are called “super scalar” machines. A supercomputer comprises thousands of microprocessors working in parallel. A vector calculation such as EQ(1) is broken into small pieces executed in different microprocessors in parallel to achieve high performance. For EQ(1), if we can divide the job into N pieces and ask N CPUs to execute them in parallel. The job can be finished within one instruction cycle. Using scalar machine to do the same job will take N instruction cycles. Supercomputers are optimized for vector calculations so that they are also called “vector machine”. IBM manufactured the BlueGene/L supercomputer system that achieved 36 trillion instructions per second. The system can have as many as 130,000 processors working in parallel. NASA, SGI, and intel deployed the “Columbia” computer system that achieved sustained performance of 42.7 trillion instructions per second with 10,240 CPU. These two systems use commercial microprocessors working at parallel processing mode to support vector operations. NEC SX-8 supercomputer system uses customized processors while each processor is a vector processor that can support vector operations at 16 billion instructions per second. A system comprises 4096 such specialized vector processors is proven to support 64 trillion instructions per second. It is very important to remember that the microprocessors in supercomputers still need to communicate with external memory devices. The microprocessors in a supercomputer can execute billions of instructions per second as soon as they do not need to access data externally. Whenever the microprocessors need the support of external devices, the whole system slows down. Therefore, a supercomputer is only useful to support software that can be broken into small looping blocks.

For example, after we finished calculating EQ(1), want to execute a calculation
Sum=A(1)+A(2)+A(3)+ . . . +A(N) EQ(2)

For EQ(1), we can divide the job into N pieces and ask N CPUs to execute them in parallel. However, for a serial operation such as EQ(2), a supercomputer can only use one of its CPUs to execute the calculation so that its performance is the same as a common scalar machine. Unfortunately, most of software requires serial operations so that prior art supercomputers are only useful for limited applications (mostly scientific applications). Whenever execution units in supercomputers need to access data or instructions externally, the speed of the system is slowed down to the speed of external memory devices. Improving memory access performance is therefore the key to improve computer performance for vector machines, graphic controllers, or scalar machines.

The Web-IC data transfer methods of the present invention provide ideal solutions to improve the performance of computer systems. FIG. 5(c) shows simplified symbolic diagrams for a Web-IC computer device. This Web-IC (541) comprises large number of separable dice (542) while each separable die (542) comprises a plurality of functional dice (543-547). We can have many types of functional dice. For example, the dice marked with “I” in FIG. 5(c) are integer microprocessors (543); the dice marked with “F” in FIG. 5(c) are floating point microprocessors (544)); the dice marked with “O” in FIG. 5(c) are input/output controllers (545) with external interfaces; the dice marked with “G” in FIG. 5(c) are graphic controllers (546); and the die marked with “T” in FIG. 5(c) is a address generation unit (547). All these functional dice (543-547) can have similar structures as illustrated in the magnified block diagram (543) in FIG. 5(c). This die (543) comprises multiple pipeline execution units (556, marked as “EU” in FIG. 5(c)), high speed random access memory devices (555, marked as “RAM” in FIG. 5(c)), register files (557, marked as “Rg” in FIG. 5(c)), and a local lookup table (558, marked as “Tb” in FIG. 5(c)). This functional die (543) also has Web-IC signal paths (551, represented by arrows in FIG. 5(c)) to communicate to the function die at right hand side, Web-IC signal paths (552) to communicate to the function die on top, Web-IC signal paths (553) to communicate to the function die at left hand side, and Web-IC signal paths (554) to communicate to the function die at bottom side. Different types of functional dice (543-547) can have similar structures but different execution units—an integer microprocessor (543) has ALU as its EU, a floating point die (544) has floating point unit as its EU, a graphic die (544) has a graphic controller as its EU, and a I/O die (545) has bounding pads and I/O control circuits. All the functional dice (543-547) in the Web-IC (541) are equipped with similar Web-IC signal paths (551-554), forming a web of high performance data transfer system. The size of each function die is controlled to be small (e.g. 1 mm²) to achieve high performance and high yields.

Prior art computer systems bring information close to execution units by making multiple copies of data in different levels of memory devices, and rely on the principle of locality to achieve reasonable efficiency. A Web-IC computer of the present invention uses many copies of execution units distributed among local memory devices as shown in the example in FIG. 5(c). Each functional die (453-457) comprises local storage units and local execution units with a size much smaller than prior art IC devices. They can easily execute billions of instructions per second when the required data and instructions are stored in location memory devices. When the software require memory operations external to individual function dice, we can access required data using Web-IC data transfers that are capable of transferring trillions of bits per second. FIG. 5(d) is a float chart that shows the procedures for a memory access of a Web-IC computer. When an execution unit needs instructions or data from memory, it checks local lookup table (558) first. If the information can be found in local memory devices (555), the results are sent to register files or instruction decoders directly, followed by some book keeping activities such as updating flags and updating higher level storage devices. If the information is not stored in local cache, the EU sends request through Web-IC data transfer to nearby lookup table (547), and find the location of needed data. If the information can be found in the same Web-IC, Web-IC data transfer can fetch the data within a few Web-IC transfer steps, and the results are sent to register files or instruction decoders directly, followed by some book keeping activities such as updating flags in the lookup tables. If the information is not stored in the Web-IC, the request is send to I/O dice (545) that executes I/O access from external devices. The results are sent to register files or instruction decoders directly, followed by some book keeping activities such as updating flags. A copy of the information, including nearby data, are also stored into the Web-IC (541) so that we can avoid these slow devices as much as possible in the future.

The Web-IC data access procedures in FIG. 5(d) are dramatically simplified and by far more efficient that prior art methods shown in FIG. 5(b). In addition, the Web-IC (541) has the flexibility to support large number of data access procedures in parallel, achieving a performance that is not imaginable for prior art computers. For example, we can use a 12 inch wafer as a single Web-IC. Using current art 65 nm IC manufacture technology, each function unit can be smaller than 1 mm² while equipped with dual pipeline execution units and more than 1M bits of high speed SRAM as local memory. Each function die can easily executes 8 billions of instructions per second. A 12 inch wafer will have more than 70,000 function dice. Using Web-IC architecture we have the flexibility to bypass failed dice, achieving extremely high yields (98% or better). That means we can have 70,000 executing units capable of parallel execution of 560 trillion instructions per second. In addition, we also have more than 8 GB (billions of bytes) of high speed SRAM as supporting memory. Most of time, the execution units use those high speed SRAM as local cache memory operating at billions of cycles per second. For the rare case when the execution units need memory access from other dice, the Web-IC signal transfer can fetch the data within a few ns. With 8 GB of high speed memory, we almost never need to use external MSUs except during the initialization procedures. The Web-IC in FIG. 5(c) is not only efficient to support vector operations like supercomputers, it is also highly efficient in supporting serial operations such as EQ(2) because we can move data at extremely high bandwidth through Web-IC signal transfers. The Web-IC is also ideal to support graphic applications using its large storage capacity and parallel processing capabilities. Most of the I/O functions currently supported by separated chip sets also can be integrated into the same Web-IC. A Web-IC of the present invention is therefore able to integrate all the major components of a prior art supercomputer into a single IC while achieving higher performance at much lower cost. In addition, the Web-IC is able to avoid the limitations of prior art supercomputers.

While specific embodiments of the invention have been illustrated and described herein, it is realized that other modifications and changes will occur to those skilled in the art. For example, we certainly can have more types of functional dice, or less types of functional dice in the Web-IC shown in FIG. 5(c). We also have the flexibility to cut a wafer into smaller Web-IC to support lower cost computers such as personal computers or work stations.

Application Example: Field Programmable Gate Arrays (FPGAs)

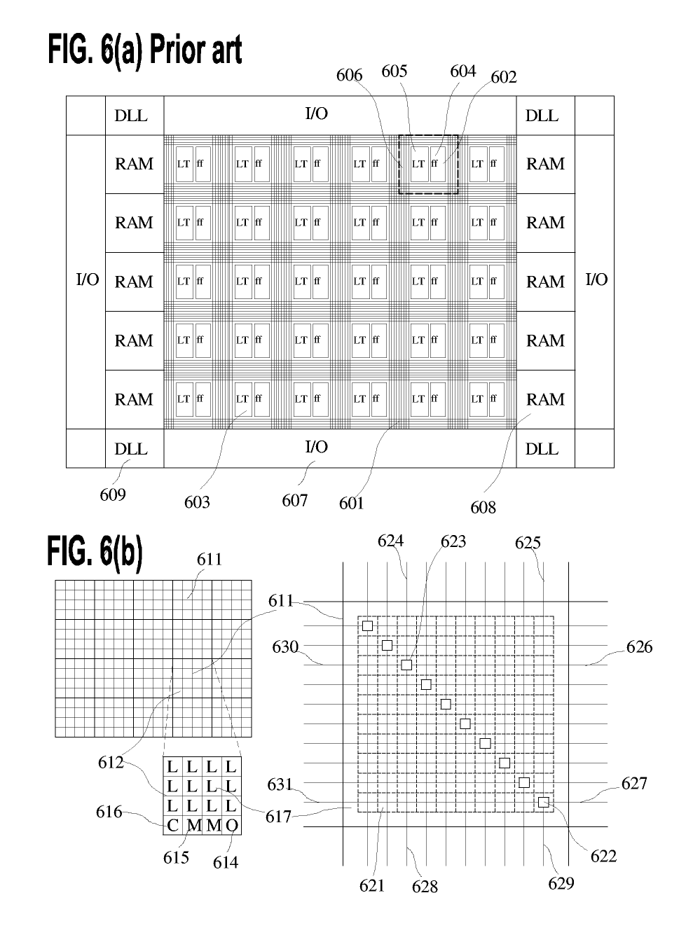

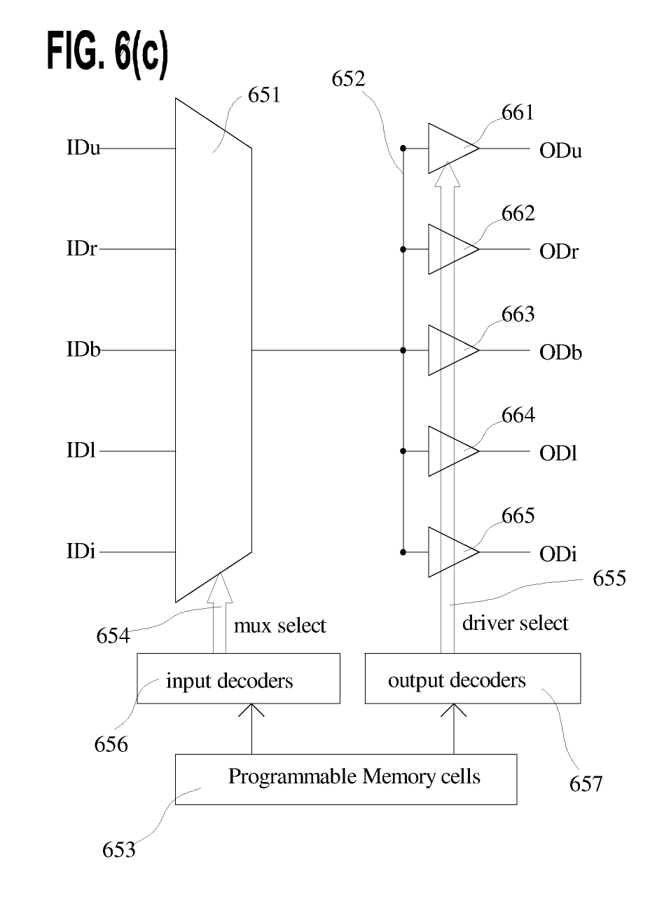

FPGAs are programmable logic devices (PLD) that use gate array architectures to achieve high gate density. Currently, Xilinx and Altera are the dominating FPGA manufactures. Their web sites provide excellent documentations for prior art FPGAs. FIG. 6(a) is a simplified block diagram illustrating the basic structures of a typical prior art FPGA device (601). Typically, the core of an FPGA device is a programmable logic gate array (603) that comprises a plurality of repeating logic cells (602). One of such logic cell (602) is circled by dashed lines in FIG. 6(a). The logic cell (602) typically comprises a 4-input lookup table (605, represented by “LT” in FIG. 6(a)), a flip-flop (604, represented by “ff” in FIG. 6(a)), and programmable routing channels (606, represented by horizontal and vertical lines in FIG. 6(a)). FIG. 6(a) is not drawn to scale; a FPGA device can have millions of such logic cells. The lookup table (605) can be configured to support wide varieties of logic functions by writing into programmable memory cells (not shown). The flip-flop (604) also can be configured to support different types of storage elements such as a flip-flop with reset, a flip-flop with set, a latch, and so on. The programmable routing channels (606) provide connection lines that can be programmed to connect different components in the FPGA device (601). Each line in the programmable routing channel provides programmable connections to many components in the FPGA device (601). The actual connection is controlled by programmable memory cells (not shown). Beside the programmable logic gate array, current art FPGAs typically have supporting modules such as memory blocks (608, labeled as “RAM” in FIG. 6(a)), delay locked loop (609, labeled as “DLL” in FIG. 6(a)), and I/O modules (607). The functions of logic cells (602) and the connections between different components are all controlled by programmable memory cells so that the function of the device can be changed by writing different values into programmable memory cells. The software provided by FPGA manufacturers typically can support most of logic functions that can be coded by hard ware description languages (HDLs) such as verilog or VHDL.

Prior art FPGA is very flexible. The design costs to program a FPGA are much lower than the design costs for making application specific integrated circuits (ASIC). Most important of all, logic design errors can be corrected by reprogramming the device instead of re-manufacture the whole IC.

The major limitations of prior art FPGAs come from the programmable routing channels (606). The programmable routing channel can be re-configured into different connections by writing different values into programmable memory cells. The routing channels (606) can be configured to connect any two components within the FPGA IC chip (601). To achieve that, each line in the programmable routing channel has programmable connections to many components in the FPGA device. Therefore, each line has heavy loading, limiting the performance for signal transfers. The prior art FPGA is very effective if the connections of the programmable routing channels (606) can be limited to support only local short connections. Whenever we need to use the routing channels to support long distance connections (a few mm), the speed of the whole chip will be slowed down. For existing FPGAs, the typical delay time for local logic operations is around 1 ns, while the typical delay time for long distance connections is 5-8 ns. In other words, the delay caused by the routing channels is the limiting factor for prior art FPGAs. Unlike Web-IC connections, the prior art FPGA programmable routing channels provide one possible configuration between two given points in the device. A defect in the programmable routing channel can fail the whole chip because the chip will no longer be able to support all possible configurations. Because of the programmable routing channels (606), prior art FPGAs are well known to have relatively low yield and high unit price. Prior art FPGA devices have fixed resources in each give product. The actual applications usually do not need most of the resources in the FPGAs, causing a lot of wastes. Due to these cost and performance limitations, prior art FPGAs are limited to high unit cost, low performance (relative to ASIC) applications. Most of mass production applications still relay on conventional ASIC devices.

Web-IC architecture of the present invention can remove those limitations for prior art FPGAs. FIG. 6(b) is a simplified symbolic diagram showing the structures for a Web-IC FBGA device (611) with magnified views for its separable dice and functional dice. This Web-IC (611) comprises a plurality of separable dice (612) while each separable die comprises a plurality of functional dice (614-617). We can have many types of functional dice. For example, the dice marked with “L” in FIG. 6(b) are programmable logic gate arrays (617); the dice marked with “M” in FIG. 6(b) are memory modules (615); the die marked with “O” in FIG. 6(b) is input/output module (614) with external interfaces; and the die marked with “C” in FIG. 6(c) is clock module (546) with phase locked loops and clock drivers. All these functional dice (614-617) can have Web-IC signal transfer circuits as illustrated in the magnified block diagram in FIG. 6(b). In this example, the functional die (617) comprise an array of logic cells (621) represented by rectangles bounded by dashed lines. The structures of the logic cells (612) can be the same as prior art logic cells (602), and they also can communicate using prior art programmable routing channels (606) as shown in FIG. 6(a). The major difference is that the programmable routing channels (not shown) are used only for short distance local connections, while long distance connections are provided by Web-IC connections of the present invention. In this example, there are a plurality of Web-IC control circuits (622, 623) represented by solid squares in FIG. 6(b). Each Web-IC control circuits (622, 623) are connected to the Web-IC control circuits in nearby dice though Web-IC connections (represented by solid lines connected to Web-IC control circuits in FIG. 6(b)). For example, the Web-IC control circuit (622) at the lower right corner is connected to a Web-IC control circuit (not shown) in a die to the right through an Web-IC connection line (627); it is connected to another Web-IC control circuit (not shown) in a die to the top through an Web-IC connection line (625); it is connected to another Web-IC control circuit (not shown) in a die to the left through an Web-IC connection line (631); and it is connected to another Web-IC control circuit (not shown) in a die to the bottom through an Web-IC connection line (629). For another example, another Web-IC control circuit (623) is connected to a Web-IC control circuit (not shown) in a die to the right through an Web-IC connection line (626); it is connected to another Web-IC control circuit (not shown) in a die to the top through an Web-IC connection line (624); it is connected to another Web-IC control circuit (not shown) in a die to the left through an Web-IC connection line (630); and it is connected to another Web-IC control circuit (not shown) in a die to the bottom through an Web-IC connection line (628). Using programmable routing channels, these Web-IC control circuits (622, 623) also can communicate with local circuit elements (621).

FIG. 6(c) shows a schematic diagram for one example design of the Web-IC control circuits (622, 623) in FIG. 6(b). This circuit comprise a multiplexer (651) that can selectively connect to the Web-IC signal from the top (IDu), the Web-IC signal from the right (IDr), the Web-IC signal from the bottom (IDb), the Web-IC signal from the left (IDI), or an internal signal (IDi) from nearby circuits. This multiplexer (651) is controlled by select signals (654) provided by input decoders (656) controlled by programmable memory cells (653). The output signal (652) of the multiplexer (651) is connected to a driver (661) that drives the Web-IC signal to the top (ODu), a driver (662) that drives the Web-IC signal to the right (ODr), a driver (663) that drives the Web-IC signal to the bottom (ODb), a driver (664) that drives the Web-IC signal to the left (ODI), and a driver (665) that drives an internal signal (ODi) to nearby circuits. These drivers (661-665) are controlled by driver select signals (655) provided by output decoders (657) controlled by programmable memory cells (653). By writing different values to the programmable memory cells (653), the Web-IC control circuit in FIG. 6(c) can receive/transfer data to any direction of nearby dice or to nearby circuits. Combining programmable routing channels and Web-IC connections, the Web-IC FPGA device (611) in FIG. 6(b) is able to make programmable connections between any two elements in the Web-IC to support all the functions supported by prior art FPGA devices. In addition, the Web-IC FPGA device (611) has many advantages over prior art FPGA devices.

The Web-IC is divided into many small functional dice (614-617). The programmable routing channels within each functional die only need to support short distance connections so that the structures of the routing channels are much simpler than prior art FPGA routing channels, and the loading of routing lines are much lower, resulting in much better performance for local connections. The long distance connections are provided by Web-IC networks of the present invention. A local circuit use local programmable routing channel to communicate with a Web-IC control circuit (622, 623). The Web-IC control circuit uses a series of Web-IC connections to reach another Web-IC control circuit, which connects to the destination circuit using local routing channels. Each driver (661-665) in the Web-IC control circuits (622, 623) only need to driver a short and simple Web-IC line, achieving high performance and low power. Most of current art IC manufacture technologies should be able to support driver delay time less than 0.05 ns in this configuration. Long distance signal connections are achieved by series of short Web-IC connections to achieve excellent performance. The delay time is typically one order of magnitude shorter than prior art FPGA routing delay time. The Web-IC connections also can have multiple possible paths to connect two given circuits, allowing the capability to bypass defected circuits. If there are bad dice in the Web-IC FPGA device, we simply go around it using the web-like structures of Web-IC connections. Therefore, we can have extremely large FPGA while achieving excellent yield. The Web-IC structures also allow us to cut different sizes of Web-IC from the same design to adapt for different applications. For a simple application, we can use a Web-IC with less functional dice. For a complex application, we can use a Web-IC with more functional dice. The Web-IC FPGA can achieve performance and cost similar to ASIC, making it suitable for many applications that prior art FPGA can not support.

While specific embodiments of the invention have been illustrated and described herein, it is realized that other modifications and changes will occur to those skilled in the art. For example, in the above example the Web-IC control circuits are distributed along a diagonal line while they can be distributed in any configuration such as a two-dimensional arrays. It is a good idea for the Web-IC control signal to have a flip-flop to support pipelined signal transfers. Besides FPGA, the present invention is equally suitable for other types of programmable logic devices such as programmable logic arrays (PLA). The programmable memory cells used to configure the devices in our examples also can be replaced with fuses, EPROM, or other types of programmable circuits.

The present invention is a method for signal transfers between a plurality of integrated circuit blocks on the same semiconductor substrate, the method comprising the steps of: (a) forming signal transfer paths between and only between nearby integrated circuit blocks on the same semiconductor substrate, (b) providing control circuits to control signal transfers using said signal transfer paths between nearby integrated circuit blocks wherein said control circuits allow multiple direction signal transfers from a integrated circuit block to a plurality of nearby integrated circuit blocks, and allow transfers between far away integrated circuit blocks through paths comprising a series of said signal transfer paths between nearby integrated circuit blocks, (c) forming a web network of signal transfer paths between a plurality of integrated circuit blocks using said signal transfer paths between nearby circuit blocks where multiple signal transfer paths are available for signal transfers between two points in the integrated circuits on the same wafer. The Web-IC signals transfer methods of the present invention achieve extremely high signal transfer performance, and effectively improve cost and power efficiency for IC devices. The methods and the structures of the present invention have been shown by application examples in database search engines, routers, computers, and programmable logic devices.

While specific embodiments of the invention have been illustrated and described herein, it is realized that other modifications and changes will occur to those skilled in the art. It is therefore to be understood that the appended claims are intended to cover all modifications and changes as fall within the true spirit and scope of the invention.

What is claimed is:

1. A method for signal transfers between a plurality of integrated circuit blocks on the same semiconductor substrate, the method comprising the steps of: (a) forming signal transfer paths between and only between nearby integrated circuit blocks on the same semiconductor substrate, (b) providing control circuits to control signal transfers using said signal transfer paths between nearby integrated circuit blocks where said control circuits allow multiple direction signal transfers from a integrated circuit block to a plurality of nearby integrated circuit blocks, and allow transfers between far away integrated circuit blocks through paths comprising a series of said signal transfer paths between nearby integrated circuit blocks, (c) forming a web network of signal transfer paths between a plurality of integrated circuit blocks using said signal transfer paths between nearby circuit blocks where multiple signal transfer paths are available for signal transfers between two points in the integrated circuits on the same wafer.

2. A signal transfer network for signal transfers between a plurality of integrated circuit blocks on the same semiconductor substrate, said signal transfer network comprises a plurality of signal transfer paths between and only between nearby integrated circuit blocks on the same semiconductor substrate, and control circuits controlling multiple direction signal transfers from a integrated circuit block to a plurality of nearby integrated circuit blocks, wherein said signal transfer paths between nearby integrated circuit blocks forming a web network, and provide multiple signal transfer paths available for signal transfers between two points in the integrated circuits on the same wafer.
